(19) United States
(12) Patent Application Publication
(10) Pub. No.: US 2025/0241150 A1
(43) Pub. Date: Jul. 24, 2025

(54) DISPLAY DEVICE, METHOD FOR FABRICATION THEREOF, AND HEAD MOUNTED DISPLAY DEVICE

(71) Applicant: Samsung Display Co., LTD., Yongin-si (KR)

(72) Inventors: Sin Chul KANG, Yongin-si (KR); Dae Ho SONG, Yongin-si (KR); Yo Han LEE, Yongin-si (KR); Kyung Ho KIM, Yongin-si (KR); Sug Woo JUNG, Yongin-si (KR); Joo Sun CHOI, Yongin-si (KR)

(21) Appl. No.: 18/940,520

(22) Filed: Nov. 7, 2024

(30) Foreign Application Priority Data
Jan. 18, 2024 (KR) 10-2024-0008141

(51) Int. Cl. H10K 59/131; H10K 59/12; H10K 59/123

(52) U.S. Cl. CPC H10K 59/131; H10K 59/1201; H10K 59/123

(57) ABSTRACT

A display device, a method for fabrication thereof, and a head mounted display device are provided. A display device includes a first single crystal semiconductor substrate on which a plurality of first transistors is formed, a driving circuit layer being on the first single crystal semiconductor substrate; a second single crystal semiconductor substrate on the first single crystal semiconductor substrate, the second single crystal semiconductor substrate having thereon a display element layer including a plurality of sub-pixels including a plurality of light emitting elements; and a connection wiring layer between the display element layer and the first single crystal semiconductor substrate, where the second single crystal semiconductor substrate includes a plurality of first through holes, and a conductive via in each of the plurality of first through holes, the conductive via being electrically connected to the light emitting element of each of the plurality of sub-pixels.

### CROSS-REFERENCE TO RELATED APPLICATION

The present application claims priority to and the benefit of Korean Patent Application No. 10-2024-0008141, filed on Jan. 18, 2024, in the Korean Intellectual Property Office, the entire disclosure of which is incorporated by reference herein.

### BACKGROUND

### 1. Field

The present disclosure relates to a display device, a method for fabrication thereof, and a head mounted display device.

### 2. Description of the Related Art

A head mounted display device (HMD) is an image display device that is worn on a user's head in the form of glasses or a helmet to form a focus at a close distance in front of the user's eyes. The head mounted display device may implement virtual reality (VR) and/or augmented reality (AR).

The head mounted display device magnifies an image displayed on a small display device by using a plurality of lenses, and displays the magnified image. Therefore, the display device applied to the head mounted display device may suitably provide high-resolution images, for example, images with a resolution of 3000 PPI (Pixels Per Inch) or higher. To this end, an organic light-emitting diode (OLED) on silicon (OLEDoS), which is a high-resolution small organic light-emitting display device, is used as the display device applied to the head mounted display device. The OLEDoS is an image display device in which an organic light-emitting diode (OLED) is located on a semiconductor wafer substrate on which a complementary metal oxide semiconductor (CMOS) is located.

### SUMMARY

Aspects and features of embodiments of the present disclosure provide a micro-display device including a plurality of different single crystal semiconductor substrates, and a head mounted display device including the same.

Aspects and features of embodiments of the present disclosure also provide a micro-display device that is implemented by efficient disposition design of through holes connecting two different semiconductor substrates and a method for fabrication thereof.

However, aspects and features of embodiments of the present disclosure are not restricted to those set forth herein. The above and other aspects and features of embodiments of the present disclosure will become more apparent to one of ordinary skill in the art to which the present disclosure pertains by referencing the detailed description of the present disclosure given below.

According to one or more embodiments of the disclosure, a display device includes a first single crystal semiconductor substrate on which a plurality of first transistors is formed, a driving circuit layer being on the first single crystal semiconductor substrate; a second single crystal semiconductor substrate on the first single crystal semiconductor substrate, the second single crystal semiconductor substrate having thereon a display element layer including a plurality of sub-pixels including a plurality of light emitting elements; and a connection wiring layer between the display element layer and the first single crystal semiconductor substrate, wherein the second single crystal semiconductor substrate includes a plurality of first through holes, and a conductive via in each of the plurality of first through holes, the conductive via being electrically connected to the light emitting element of each of the plurality of sub-pixels, and wherein the connection wiring layer includes a connection line electrically connected to the conductive via and the driving circuit layer.

The plurality of first through holes respectively corresponds to the plurality of sub-pixels, and wherein the first through holes that respectively correspond to neighboring sub-pixels from among the plurality of sub-pixels are spaced in a diagonal direction.

The display device further includes a plurality of pixels, each of the plurality of pixels having three sub-pixel portions respectively corresponding to the plurality of sub-pixels, wherein a distance between centers of adjacent ones of the first through holes in the pixel is 61.0328% or less of a distance between same sub-pixel portions in neighboring pixels.

The display device further includes a plurality of conductive patterns on the second single crystal semiconductor substrate and respectively correspond to the plurality of sub-pixels.

The plurality of first through holes respectively overlaps the conductive patterns, and wherein the conductive via is connected to the conductive pattern.

A first electrode of each of the plurality of light emitting elements at least partially overlaps the conductive pattern.

The connection wiring layer is located between the second single crystal semiconductor substrate and the first single crystal semiconductor substrate.

Some of the plurality of first through holes overlap the first single crystal semiconductor substrate, and other ones of the plurality of first through holes do not overlap the first single crystal semiconductor substrate.

The connection wiring layer is located between the second single crystal semiconductor substrate and the display element layer.

The plurality of first through holes overlaps the first single crystal semiconductor substrate.

The display device further includes a plurality of signal terminals on the first single crystal semiconductor substrate, wherein the second single crystal semiconductor substrate includes a plurality of second through holes overlapping the plurality of signal terminals.

An area of the first single crystal semiconductor substrate in a plan view is smaller than an area of the second single crystal semiconductor substrate in the plan view.

The display device further includes a passivation layer around the first single crystal semiconductor substrate and overlapping the second single crystal semiconductor substrate.

According to one or more embodiments, a method for fabrication of a display device, the method includes: preparing a first wafer substrate and a second wafer substrate different from each other; forming a plurality of first transistors on the first wafer substrate, and forming a plurality of through holes at least partially penetrating the second wafer substrate and a plurality of conductive vias respectively located in the plurality of through holes in the second wafer substrate; dividing the first wafer substrate into a plurality of first single crystal semiconductor substrates, and disposing the first single crystal semiconductor substrate on one surface of the second wafer substrate; forming a planarization layer covering the one surface of the second wafer substrate and the first single crystal semiconductor substrates attached to the one surface; forming a display element layer including a plurality of light emitting elements on an other surface of the second wafer substrate opposite to the one surface; and dividing the second wafer substrate into a plurality of second single crystal semiconductor substrates in which the display element layer is formed on an other surface and the first single crystal semiconductor substrate is located on the one surface, wherein the plurality of conductive vias are respectively connected to the plurality of light emitting elements, and at least some of the plurality of through holes overlap the first single crystal semiconductor substrate.

The plurality of through holes are spaced from other neighboring through holes in a diagonal direction.

The method further includes, after forming the plurality of through holes and the plurality of conductive vias, etching the second wafer substrate to reduce its thickness; and forming a connection wiring layer including a plurality of connection lines connected to the conductive via on the one surface of the second wafer substrate where the through holes are not formed, wherein the first single crystal semiconductor substrate is attached onto the connection wiring layer.

Some of the plurality of through holes overlap the first single crystal semiconductor substrate, and others do not overlap the first single crystal semiconductor substrate.

The method further includes, after forming the plurality of through holes and the plurality of conductive vias, forming a connection wiring layer including a plurality of connection lines connected to the conductive via on the other surface of the second wafer substrate opposite the one surface; and etching the second wafer substrate to reduce its thickness, wherein the first single crystal semiconductor substrate is attached onto the one surface of the second wafer substrate.

The plurality of through holes overlaps the first single crystal semiconductor substrate.

According to one or more embodiments, a head mounted display device includes a frame mounted on a user's body and corresponding to left and right eyes; a plurality of display devices located in the frame; and a lens on each of the plurality of display devices, wherein the display device includes a first single crystal semiconductor substrate on which a plurality of first transistors is formed, a driving circuit layer being on the first single crystal semiconductor substrate; a second single crystal semiconductor substrate on the first single crystal semiconductor substrate, the second single crystal semiconductor substrate having thereon a display element layer having a plurality of sub-pixels including a plurality of light emitting elements; and a connection wiring layer between the display element layer and the first single crystal semiconductor substrate, wherein the second single crystal semiconductor substrate includes a plurality of first through holes, and a conductive via in each of the plurality of first through holes, the conductive via being electrically connected to the light emitting element of each of the plurality of sub-pixels, and wherein the connection wiring layer includes a connection line electrically connected to the conductive via and the driving circuit layer.

The display device according to one or more embodiments may include two different single crystal semiconductor substrates, and the fabrication process of the single crystal semiconductor substrate disposed on the lower portion is capable of producing a large quantity per unit wafer substrate, thereby improving fabrication yield.

However, aspects according to the embodiments of the present disclosure are not limited to the above and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view of a display device according to one or more embodiments;

FIG. 2 is a plan view illustrating an example of the driving unit shown in FIG. 1;

FIG. 3 is a plan view illustrating an example of a display part shown in FIG. 1;

FIG. 4 is a block diagram illustrating a display device according to one or more embodiments;

FIG. 5 is an equivalent circuit diagram of one pixel according to one or more embodiments;

FIG. 6 is a schematic cross-sectional view of a display device according to one or more embodiments;

FIG. 7 is a schematic diagram showing a rear surface of a display device according to one or more embodiments;

FIG. 8 is a schematic cross-sectional view of a driving unit according to one or more embodiments;

FIG. 9 is a plan view showing a pixel defining layer, and first electrodes and emission areas of a plurality of sub-pixels disposed in a display area of a display part according to one or more embodiments;

FIG. 10 is a plan view showing a pixel defining layer, and first electrodes and emission areas of a plurality of sub-pixels disposed in a display area of a display part according to one or more embodiments;

FIG. 11 is a cross-sectional view illustrating a part of a display part according to one or more embodiments;

FIG. 12 is a plan view showing a schematic disposition of pixel areas and through holes disposed in a display area of a display part according to one or more embodiments;

FIG. 13 is a flowchart illustrating a method for fabrication of a display device according to one or more embodiments;

FIGS. 14-19 are diagrams sequentially showing a fabrication process of a display device according to one or more embodiments;

FIGS. 20-30 are cross-sectional views sequentially illustrating a fabrication process of a display device according to one or more embodiments;

FIG. 31 is a cross-sectional view illustrating a part of a display part according to one or more embodiments;

FIG. 32 is a plan view showing a schematic disposition of pixel areas and through holes disposed in a display area of the display part of the display device in FIG. 31;

FIG. 33 is a schematic cross-sectional view of a display device according to one or more embodiments;

FIG. 34 is a schematic diagram showing the rear surface of the display device of FIG. 33;

FIGS. 35-37 are cross-sectional views showing a part of the fabrication process of the display device of FIG. 33;

FIG. 38 is a perspective view illustrating a head mounted display device according to one or more embodiments;

FIG. 39 is an exploded perspective view showing an example of the head mounted display device of FIG. 38; and

FIG. 40 is a perspective view illustrating a head mounted display device according to one or more embodiments.

### DETAILED DESCRIPTION

Aspects and features of embodiments of the present disclosure and methods of accomplishing the same may be understood more readily by reference to the detailed description of embodiments and the accompanying drawings. The described embodiments are provided as examples so that the present disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure. The present disclosure covers all modifications, equivalents, and/or replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and/or regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching and/or shading conveys and/or indicates any preference and/or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural and/or functional descriptions disclosed herein are merely illustrative for the purpose of describing embodiments according to the concept of the present disclosure. Thus, embodiments disclosed herein should not be construed as limited to the illustrated shapes of elements, layers, and/or regions, but are to include deviations in shapes that result from, for instance, manufacturing.

For example, an implanted region illustrated as a rectangle will, typically, have rounded and/or curved features and/or a gradient of implant concentration at its edges rather than a binary change from implanted to non-implanted region. Likewise, a buried region formed by implantation may result in some implantation in the region between the buried region and/or the surface through which the implantation takes place.

Spatially relative terms, such as “beneath,” “below,” “lower,” “lower side,” “under,” “above,” “upper,” “upper side,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below and/or to a side of a second object, and vice versa. Additionally, the term “overlap” may include stack, face or facing, extending over, covering, or partly covering and/or any other suitable terms as would be appreciated and understood by those of ordinary skill in the art. The expression “not overlap” may include meaning, such as “apart from” and/or “set aside from” and/or “offset from” and any other suitable equivalents as would be appreciated and understood by those of ordinary skill in the art. The terms “face” and “facing” may mean that a first object may directly and/or indirectly oppose a second object. In a case in which a third object intervenes between a first object and/or a second object, the first object and/or the second object may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, and/or coupled to the other element, layer, region, and/or component, and/or indirectly formed on, on, connected to, and/or coupled to the other element, layer, region, and/or component such that one or more intervening elements, layers, regions, and/or components may be present. In addition, this may collectively mean a direct and/or indirect coupling or connection and/or an integral and/or non-integral coupling or connection. For example, when a layer, region, and/or component is referred to as being “electrically connected” and/or “electrically coupled” to another layer, region, and/or component, it can be directly electrically connected and/or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” and/or “directly on,” refers to one component directly connecting and/or coupling another component, and/or being on another component, without an intermediate component.

In addition, in the present disclosure, when a portion of a layer, a film, an area, a plate, or the like is formed on another portion, a forming direction is not limited to an upper direction but includes forming the portion on a side surface and/or in a lower direction. On the contrary, when a portion of a layer, a film, an area, a plate, and/or the like is formed “under” another portion, this includes not only a case where the portion is “directly beneath” another portion but also a case where there is further another portion between the portion and another portion. Meanwhile, other expressions describing relationships between components, such as “between,” “immediately between” and/or “adjacent to” and/or “directly adjacent to,” may be construed similarly. It will be understood that when an element or layer is referred to as being “between” two elements or layers, it can be the only element or layer between the two elements or layers, or one or more intervening elements or layers may also be present.

For the purposes of the present disclosure, expressions such as “at least one of,” or “any one of,” and/or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, and/or portion. Thus, a first element, component, region, layer and/or section described below could be termed a second element, component, region, layer or section, without departing from the spirit and/or scope of the present disclosure. The description of an element as a “first” element may not require and/or imply the presence of a second element or other elements. The terms “first,” “second,” etc. may also be used herein to differentiate different categories and/or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and/or “including,” when used in the present disclosure, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and/or other electronic circuits. This may be formed using a semiconductor-based manufacturing technique and/or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the spirit and scope of the present disclosure. In addition, in some embodiments, the block, unit and/or module may be physically combined into more complex blocks, units, and/or modules without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present disclosure, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

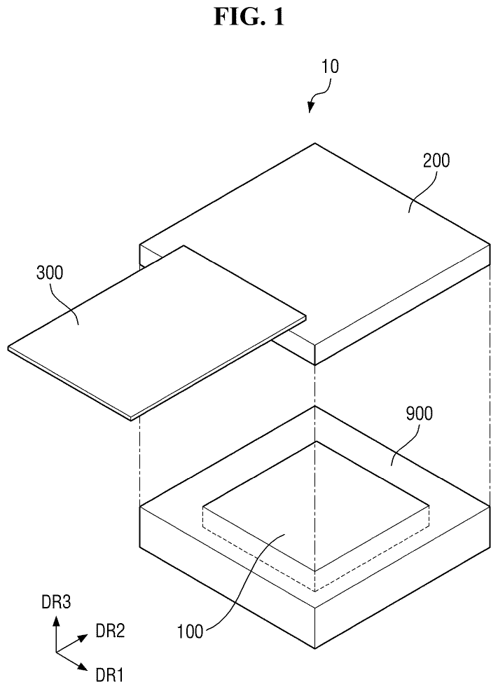

FIG. 1 is an exploded perspective view of a display device according to one or more embodiments.

Referring to FIG. 1, a display device 10 according to one or more embodiments is a device for displaying a moving image and/or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra-mobile PC (UMPC), and/or the like. For example, the display device 10 may be applied as (or may include) a display part of a television, a laptop, a monitor, a billboard, and/or an Internet-of-Things (IoT) device. Alternatively, the display device 10 may be applied to a smart watch, a watch phone, a head mounted display device (HMD) for implementing virtual reality and augmented reality, and/or the like. As used throughout the present disclosure, the term “display part” may refer to a component or part configured to display still and/or moving images, and may be used interchangeably with the term “display unit” without being limited thereto.

The display device 10 according to one or more embodiments may include a driving unit 100, a display part 200, and a circuit board 300. The display device 10 may further include a passivation layer 900 disposed around the driving unit 100.

The driving unit 100 may have a planar shape similar to a quadrilateral shape. For example, the driving unit 100 may have a planar shape similar to a rectangular shape, having one side extending in a first direction DR1 and the other side extending in a second direction DR2 crossing the first direction DR1. The one side of the driving unit 100 extending in the first direction DR1 and the other side thereof extending in the second direction DR2 may have different lengths. In the driving unit 100, a corner where one side extending in the first direction DR1 and the other side extending in the second direction DR2 meet may be right-angled and/or rounded with a suitable curvature (e.g., a predetermined curvature). The planar shape of the driving unit 100 is not limited to a rectangular shape, and may be a shape similar to another polygonal shape, a circular shape, and/or an elliptical shape.

The display part 200 may be disposed on the driving unit 100. In the display device 10, the driving unit 100 and the display part 200 may be bonded to each other. Unlike the driving unit 100, the display part 200 may have a shape similar to a square. For example, the driving unit 100 may have a planar shape similar to a square in which one side extending in the first direction DR1 and the other side extending in the second direction DR2 crossing the first direction DR1 have the same length. The planar shape of the display part 200 is not limited to a rectangular shape, and may be a shape similar to another polygonal shape, a circular shape, and/or an elliptical shape. The planar shape of the display device 10 may conform to the planar shape of the display part 200, but is not limited thereto.

According to one or more embodiments, in the display device 10, the area of the display part 200 in a plan view may be larger than the area of the driving unit 100 in a plan view. The display device 10 may include the driving unit 100 and the display part 200 having different substrates, and they may have different areas. Elements formed in the driving unit 100 and elements formed in the display part 200 may be different, and these elements may be formed individually on different substrates. The display device 10 may be fabricated by forming multiple elements with different sizes, line widths, and/or fabrication processes on different substrates and then bonding them. The display device 10 may be desirable because product performance and/or fabrication yield may be improved using the display device 10.

The circuit board 300 may be electrically connected to a plurality of pads in a pad area of the display part 200 by using a conductive adhesive member such as an anisotropic conductive film. The circuit board 300 may be a flexible printed circuit board (FPCB) with a flexible material, and/or a flexible film. Although the circuit board 300 is illustrated in FIG. 1 as being unfolded, the circuit board 300 may be bent. In this case, one end of the circuit board 300 may be disposed on the bottom surface of the driving unit 100. The other end of the circuit board 300 may be connected to the plurality of pads in the pad area of the display part 200 by using the conductive adhesive member. In one or more other embodiments, the circuit board 300 may be attached to the bottom surface of the driving unit 100.

The passivation layer 900 may be disposed on the bottom surface of the display part 200 while being around (e.g., surrounding) the driving unit 100. The passivation layer 900 may reduce a step due to the difference in the area between the driving unit 100 and the display part 200, and may also protect the driving unit 100 and the display part 200.

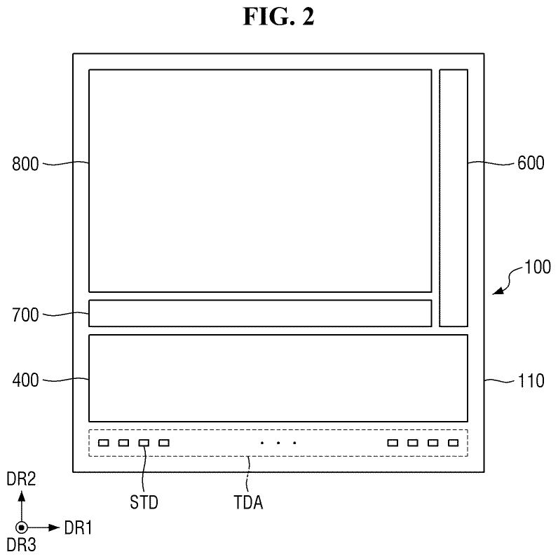

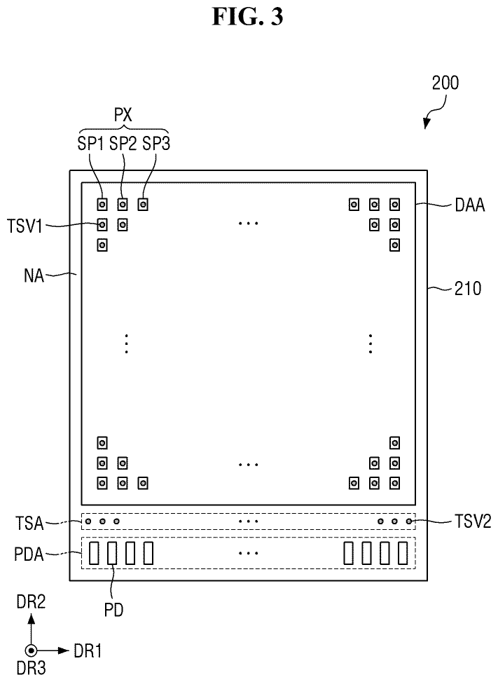

FIG. 2 is a plan view illustrating an example of the driving unit shown in FIG. 1. FIG. 3 is a plan view illustrating an example of the display part shown in FIG. 1.

Referring to FIGS. 2 and 3, the driving unit 100 of the display device 10 may include driving circuit elements of the display device 10. The driving unit 100 may include a first single crystal semiconductor substrate 110, and a driving circuit portion 400, a gate driver 600, a data driver 700, and a pixel circuit portion 800 formed on the first single crystal semiconductor substrate 110.

The first single crystal semiconductor substrate 110 may be a silicon substrate, a germanium substrate, and/or a silicon-germanium substrate. A plurality of first transistors may be formed on the first single crystal semiconductor substrate 110. The plurality of first transistors may be electrically connected to each other and constitute the driving circuit portion 400, the gate driver 600, the data driver 700, and the pixel circuit portion 800. The first transistors may be formed through a semiconductor process. For example, the plurality of transistors may be formed as complementary metal oxide semiconductor (CMOS) transistors.

The drawing illustrates that the pixel circuit portion 800 is disposed on the upper side of the driving unit 100, the data driver 700, the driving circuit portion 400, and a signal terminal area TDA are disposed below the pixel circuit portion 800, and the gate driver 600 is disposed on the right side of the pixel circuit portion 800, which is one side of the first direction DR1. However, the present disclosure is not limited thereto. In the driving unit 100, the positions of the driving circuit portion 400, the gate driver 600, the data driver 700, and the pixel circuit portion 800 may be changed in various ways according to the design structure of multiple circuit elements formed on the first single crystal semiconductor substrate 110.

In the signal terminal area TDA, a plurality of signal terminals STD arranged along the first direction DR1 may be disposed. The plurality of signal terminals STD may be electrically connected to the display part 200 and may be electrically connected to the circuit board 300 via them. The signal terminals STD may transmit an electrical signal applied from the circuit board 300 to the driving circuit portion 400, the gate driver 600, the data driver 700, and the pixel circuit portion 800.

The display part 200 may include a second single crystal semiconductor substrate 210 and a plurality of pixels PX formed on the second single crystal semiconductor substrate 210. The display part 200 may include a display area DAA where the plurality of pixels PX are disposed and a non-display area NA around (e.g., surrounding) the display area DAA along an edge or a periphery of the display area DAA. A through hole area TSA and a pad area PDA may be disposed in the non-display area NA.

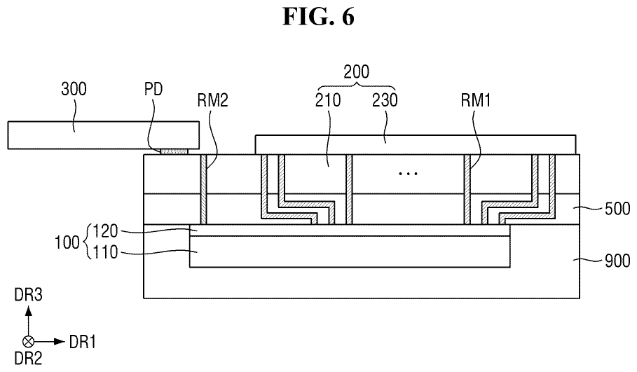

The second single crystal semiconductor substrate 210 may be a silicon substrate, a germanium substrate, and/or a silicon-germanium substrate. Unlike the first single crystal semiconductor substrate 110, transistors may not be formed on the second single crystal semiconductor substrate 210. A display element layer 230 (see FIG. 6) where a plurality of light emitting elements are disposed may be disposed on the second single crystal semiconductor substrate 210. The plurality of light emitting elements included in the display element layer may be electrically connected to the pixel circuit portion 800 formed on the first single crystal semiconductor substrate 110.

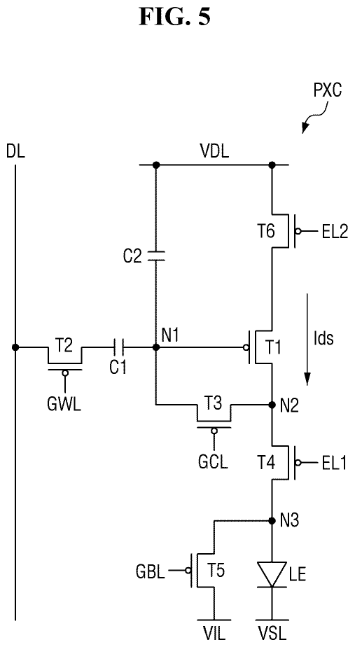

The plurality of pixels PX including light emitting elements may be disposed in the display area DAA. Each of the plurality of pixels PX may include three sub-pixels, for example, a first sub-pixel SP1, a second sub-pixel SP2, and a third sub-pixel SP3. Three sub-pixels SP1, SP2, and SP3 may constitute one pixel PX to display a color. However, the present disclosure is not limited thereto, and one pixel PX may include three or more sub-pixels. The plurality of sub-pixels SP may be arranged in a matrix form in the first direction DR1 and the second direction DR2. For example, the plurality of sub-pixels SP may be arranged along rows and columns of a matrix along the first direction DR1 and the second direction DR2. Each of the sub-pixels SP1, SP2, and SP3 may be electrically connected to a pixel circuit (pixel circuit of FIG. 5) of the pixel circuit portion 800 formed on the first single crystal semiconductor substrate 110. Each of the sub-pixels SP1, SP2, and SP3 may include light emitting elements, and the light emitting elements may emit light according to an electrical signal applied from a pixel circuit disposed in the display area DAA.

Some of the sub-pixels SP1, SP2, and SP3 disposed in the display area DAA of the display part 200 may overlap the driving unit 100 in a thickness direction of the display device 10 (e.g., a third direction DR3), and others may not overlap the driving unit 100. The driving unit 100 has a smaller area than that of the display part 200 and may be disposed adjacent to one side of the display part 200. Accordingly, only some of the sub-pixels SP1, SP2, and SP3 may overlap the driving unit 100 in the thickness direction (e.g., the third direction DR3).

According to one or more embodiment, the display part 200 of the display device 10 may include a plurality of first through holes TSV1 that overlap the display area DAA. The first through holes TSV1 may be formed to penetrate the second single crystal semiconductor substrate 210 of the display part 200. The first through holes TSV1 may form a connection path between the pixel circuit portion 800 of the driving unit 100 and each of the sub-pixels SP1, SP2, and SP3 of the display part 200. The plurality of first through holes TSV1 may be formed to respectively correspond to the sub-pixels SP1, SP2, and SP3 of the display part 200. In one or more embodiments, the number of first through holes TSV1 may be equal to the number of sub-pixels SP1, SP2, and SP3, and the first through holes TSV1 may be formed to respectively overlap the sub-pixels SP1, SP2, and SP3. However, the present disclosure is not limited thereto. The plurality of first through holes TSV1 may correspond to the respective sub-pixels SP1, SP2, and SP3, but may not necessarily be formed to overlap them. As will be described later, the plurality of sub-pixels SP1, SP2, and SP3 may be electrically connected to the pixel circuit of the pixel circuit portion 800 via connection lines disposed in the first through holes TSV1.

The non-display area NA may be disposed to be around (e.g., to surround) the display area DAA. The non-display area NA may be an area where no pixels PX are disposed and therefore no light is emitted. The through hole area TSA and the pad area PDA may be disposed in the non-display area NA.

The pad area PDA may be disposed on a lower side of the display area DAA, which is one side of the second direction DR2. A plurality of pads PD arranged along the first direction DR1 may be disposed in the pad area PDA. The circuit board 300 may be attached onto the plurality of pads PD. The pads PD may be electrically connected to the circuit board 300, and may serve to transmit the electrical signal applied from the circuit board 300 to the driving unit 100.

The through hole area TSA may be disposed between the pad area PDA and the display area DAA. A plurality of second through holes TSV2 may be formed in the through hole area TSA. The second through holes TSV2 may be connection paths of signal connection lines that electrically connect the signal terminal STD of the driving unit 100 to the circuit board 300. The plurality of second through holes TSV2 may be formed to respectively correspond to the signal terminals STD of the driving unit 100. In one or more embodiments, the number of second through holes TSV2 may be equal to the number of signal terminals STD, and the second through holes TSV2 may be formed to respectively overlap the signal terminals STD. However, the present disclosure is not limited thereto. The circuit board 300 may be electrically connected to the signal terminal STD of the driving unit 100 via the plurality of pads PD and the signal connection line disposed in the second through hole TSV2.

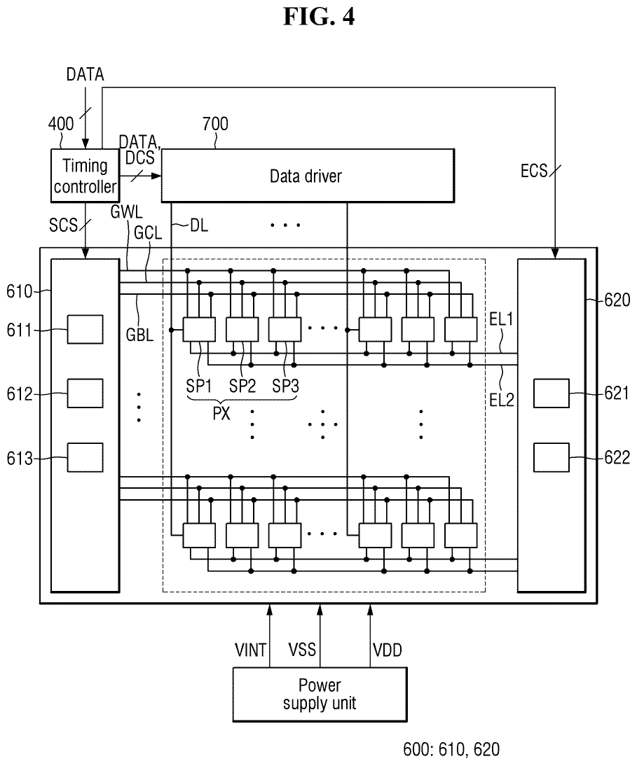

FIG. 4 is a block diagram illustrating a display device according to one or more embodiments.

Referring to FIG. 4, the driving circuit portion 400 may include a timing control circuit. In addition, the driving circuit portion 400 may further include various circuits involved in driving the display device 10, such as a gamma circuit and/or a logic circuit. The driving circuit portion 400 may include driving circuit transistors formed on the first single crystal semiconductor substrate 110.

The driving circuit portion 400 may receive digital video data DATA and timing signals from the outside. The timing control circuit may generate a scan timing control signal SCS, an emission timing control signal ECS, and a data timing control signal DCS for controlling the display part 200 according to the timing signals. The timing control circuit may output the scan timing control signal SCS to a scan driver 610 of the gate driver 600, and may output the emission timing control signal ECS to an emission driver 620 of the gate driver 600. The timing control circuit may output the digital video data DATA and the data timing control signal DCS to the data driver 700.

A power supply unit may generate a plurality of panel driving voltages by an external power voltage. For example, the power supply unit may generate a first driving voltage VSS, a second driving voltage VDD, a reference voltage, and an initialization voltage VINT and supply them to the plurality of pixels PX.

The scan timing control signal SCS, the emission timing control signal ECS, the digital video data DATA, and the data timing control signal DCS of the driving circuit portion 400 may be supplied to the plurality of pixels PX. The first driving voltage VSS, the second driving voltage VDD, and the initialization voltage VINT of the power supply unit may also be supplied to the plurality of pixels PX.

The gate driver 600 may include the scan driver 610 and the emission driver 620. The scan driver 610 may include a plurality of scan transistors formed on the first single crystal semiconductor substrate 110, and the emission driver 620 includes a plurality of emission transistors formed on the first single crystal semiconductor substrate 110. The plurality of scan transistors and the plurality of emission transistors may be formed through a semiconductor process. For example, the plurality of scan transistors and the plurality of emission transistors may be formed as CMOS transistors.

The scan driver 610 may include a first scan signal output unit 611, a second scan signal output unit 612, and a third scan signal output unit 613. Each of the first scan signal output unit 611, the second scan signal output unit 612, and the third scan signal output unit 613 may receive a scan timing control signal SCS from the driving circuit portion 400. The first scan signal output unit 611 may generate write scan signals according to the scan timing control signal SCS of the driving circuit portion 400 and output them sequentially to first scan lines GWL. The second scan signal output unit 612 may generate control scan signals in response to the scan timing control signal SCS and sequentially output them to the second scan lines GCL. The third scan signal output unit 613 may generate bias scan signals according to the scan timing control signal SCS and output them sequentially to third scan lines GBL.

The emission driver 620 may include a first emission signal output unit 621 and a second emission signal output unit 622. Each of the first emission signal output unit 621 and the second emission signal output unit 622 may receive an emission timing control signal ECS from the driving circuit portion 400. The emission driver 620 may generate emission control signals according to the emission timing control signal ECS and sequentially output them to first and second emission control lines EL1 and EL2.

The data driver 700 may receive digital video data DATA and a data timing control signal DCS from the driving circuit portion 400. The data driver 700 converts the digital video data DATA into analog data voltages according to the data timing control signal DCS and outputs the analog data voltages to data lines DL. In this case, the sub-pixels SP1, SP2, and SP3 are selected by the write scan signal of the scan driver 610, and data voltages may be supplied to the selected sub-pixels SP1, SP2, and SP3.

The pixel circuit portion 800 includes a plurality of pixel transistors formed on the first single crystal semiconductor substrate 110. The plurality of pixel transistors may be formed through a semiconductor process. For example, the plurality of pixel transistors may be formed as CMOS transistors.

The plurality of data lines DL, a plurality of scan lines GWL, GCL, and GBL, and a plurality of emission control lines EL1 and EL2 may be disposed in the pixel circuit portion 800. The plurality of scan lines GWL, GCL, and GBL and the plurality of emission control lines EL1 and EL2 may extend in the first direction DR1 and may be disposed to be spaced (e.g., spaced apart) along the second direction DR2. The plurality of data lines DL may extend in the second direction DR2, may be disposed to be spaced (e.g., spaced apart) along the first direction DR1. The pixel circuit portion 800 may be electrically connected to the pixels PX of the display part 200 to transmit electrical signals necessary for the light emitting element to emit light. The plurality of data lines DL, the plurality of scan lines GWL, GCL, and GBL, and the plurality of emission control lines EL1 and EL2 may be connected to the plurality of pixels PX of the display part 200.

FIG. 5 is an equivalent circuit diagram of one pixel according to one or more embodiments.

Referring to FIG. 5, a pixel circuit PXC of a sub-pixel may be connected to the first scan line GWL, the second scan line GCL, the third scan line GBL, the first emission control line EL1, the second emission control line EL2, and the data line DL. In addition, the pixel circuit PXC may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The pixel circuit PXC includes a plurality of transistors T1 to T6, a light emitting element LE, a first capacitor C1, and a second capacitor C2.

The light emitting element LE emits light in response to a driving current Ids flowing through the channel of the first transistor T1. The emission amount of the light emitting element LE may be proportional to the driving current Ids. The light emitting element LE may be disposed between the fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer disposed between the first electrode and the second electrode, but is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as a “driving current”) flowing between the source electrode and the drain electrode of the first transistor T1 according to a voltage applied to the gate electrode thereof. The first transistor T1 includes a gate electrode connected to a first node N1, a source electrode connected to the drain electrode of the sixth transistor T6, and a drain electrode connected to a second node N2.

The second transistor T2 may be disposed between one electrode of the first capacitor C1 and the data line DL. The second transistor T2 is turned on by the write scan signal of the first scan line GWL to connect the one electrode of the first capacitor C1 to the data line DL. Accordingly, the data voltage of the data line DL may be applied to the one electrode of the first capacitor C1. The second transistor T2 includes a gate electrode connected to the first scan line GWL, a source electrode connected to the data line DL, and a drain electrode connected to the one electrode of the first capacitor C1.

The third transistor T3 may be disposed between the first node N1 and the second node N2. The third transistor T3 is turned on by the write control signal of the second scan line GCL to connect the first node N1 to the second node N2. For this reason, because the gate electrode and the source electrode of the first transistor T1 are connected, the first transistor T1 may operate like a diode (e.g., the first transistor T1 may be diode-connected). The third transistor T3 includes a gate electrode connected to the second scan line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and a drain electrode connected to the third node N3.

The fifth transistor T5 may be disposed between the third node N3 and the third driving voltage line VIL. The fifth transistor T5 is turned on by the bias scan signal of the third scan line GBL to connect the third node N3 to the third driving voltage line VIL. Accordingly, the third driving voltage VINT of the third driving voltage line VIL may be applied to the first electrode of the light emitting element LE. The fifth transistor T5 includes a gate electrode connected to the third scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 and the second driving voltage line VDL. The second capacitor C2 includes one electrode connected to the gate electrode of the first transistor T1 (or the first node N1) and the other electrode connected to the second driving voltage line VDL.

The first node N1 is a junction between the gate electrode of the first transistor T1, the drain electrode of the third transistor T3, the other electrode of the first capacitor C1, and the one electrode of the second capacitor C2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although FIG. 5 illustrates that the pixel circuit PXC includes six transistors T1 to T6 and two capacitors C1 and C2, it should be noted that the equivalent circuit diagram of the pixel circuit PXC is not limited to the example shown in FIG. 5. For example, the number of the transistors and the number of the capacitors of the pixel circuit PXC are not limited to the example shown in FIG. 5.

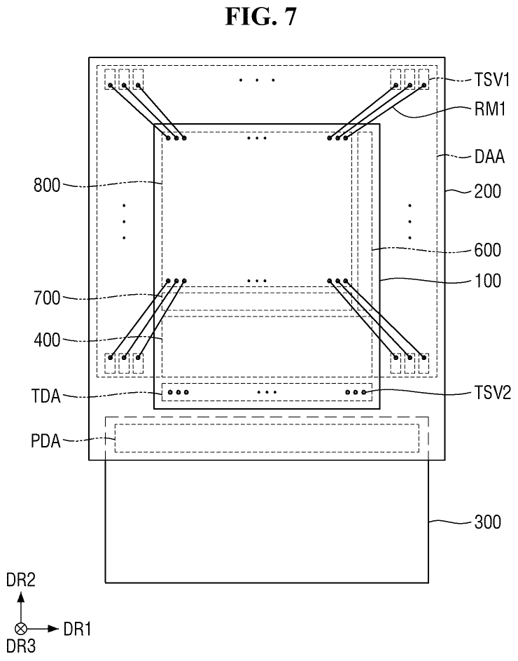

FIG. 6 is a schematic cross-sectional view of a display device according to one or more embodiments. FIG. 7 is a schematic diagram showing a rear surface of a display device according to one or more embodiments. FIG. 6 shows a schematic connection relationship of routing lines RM1 and RM2 that electrically connect the display part 200 to the driving unit 100. FIG. 7 shows a disposition of the through holes TSV1 and TSV2 and the routing lines RM1 and RM2 viewed from the rear of the display device 10.

Referring to FIGS. 6 and 7 in conjunction with FIG. 4, the display device 10 according to one or more embodiments may include the driving unit 100 including the first single crystal semiconductor substrate 110 and a driving circuit layer 120 disposed on the first single crystal semiconductor substrate 110; and the display part 200 including the second single crystal semiconductor substrate 210 and the display element layer 230 disposed on the second single crystal semiconductor substrate 210. The display device 10 may include the two different single crystal semiconductor substrates 110 and 210 overlapping each other in the third direction DR3, which is the thickness direction of the display device 10.

The driving unit 100 may include circuit elements necessary for light emission of the light emitting elements included in the display element layer 230 of the display part 200. As described above, the driving circuit layer 120 of the driving unit 100 may include the driving circuit portion 400, the gate driver 600, the data driver 700, the pixel circuit portion 800 and so forth, and the circuit elements constituting them, such as transistors and capacitors, may be formed of CMOS on the first single crystal semiconductor substrate 110.

The display part 200 may include a plurality of light emitting elements that emit light to display an image of the display device 10. The light emitting elements may be electrically connected to the circuit elements formed in the driving unit 100 to emit light.

According to one or more embodiments, in the display device 10, in a plan view, the area of the driving unit 100 or the first single crystal semiconductor substrate 110 may be smaller than the area of the display part 200 or the second single crystal semiconductor substrate 210. A plurality of transistors formed in the driving unit 100 may be formed through a semiconductor micro-process, and thus may have a very small size or line width. The driving unit 100 may be desirable because a large number of circuit elements may be disposed with a high degree of integration in the driving unit 100, and therefore power consumption may be reduced due to the miniaturization of the elements.

In addition, because the driving unit 100 includes only the circuit elements formed of CMOS on the first single crystal semiconductor substrate 110 and does not include light emitting elements, the driving unit 100 only needs to secure a space for accommodating the elements formed by the micro-process therein. It still works even if the first single crystal semiconductor substrate 110 has a smaller area than the second single crystal semiconductor substrate 210, and a large number of driving units 100 may be fabricated on a single wafer substrate on which the process of forming the driving circuit layer 120 is performed, so that the fabrication yield may be improved. In particular, because a high-cost semiconductor process is performed to fabricate the driving unit 100, such improvement in the fabrication yield of the driving unit 100 may lead to cost reduction. Further, in the display part 200, because a large number of light emitting elements can be formed on the second single crystal semiconductor substrate 210 having a relatively large area, a high-resolution display device may be implemented.

The display device 10 may include a connection wiring layer 500 disposed between the second single crystal semiconductor substrate 210 of the display part 200 and the driving circuit layer 120 of the driving unit 100. The connection wiring layer 500 may be disposed on the bottom surface of the second single crystal semiconductor substrate 210. The plurality of routing lines RM1 and RM2 may be partially disposed in the connection wiring layer 500. The routing lines RM1 and RM2 may connect the display element layer 230 of the display part 200 and the circuit board 300 to the driving unit 100. The driving circuit layer 120 of the driving unit 100 may be electrically connected to the display part 200 and the circuit board 300 through the routing lines RM1 and RM2 to transmit an electrical signal for light emission.

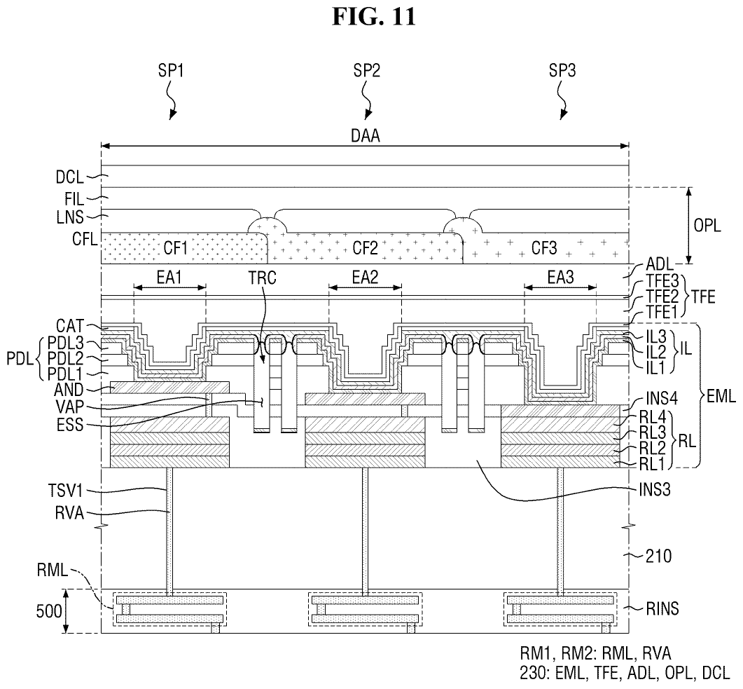

The first routing line RM1 may be connected to the sub-pixels SP1, SP2, and SP3 disposed in the display element layer 230 of the display part 200 and the pixel circuit portion 800 of the driving unit 100. In one or more embodiments, the display device 10 may include the plurality of first through holes TSV1 disposed to correspond to the sub-pixels SP1, SP2, and SP3 of the display part 200, and the first routing line RM1 may connect each of the first through holes TSV1 to the pixel circuit portion 800. While the first through holes TSV1 may be disposed throughout the display part 200 having a large area, the pixel circuit portion 800 may have a relatively small area. The first routing line RM1 may include conductive vias RVA (see FIG. 11) disposed throughout the display part 200 having the large area and connection lines RML (see FIG. 11) connecting them to the pixel circuit portion 800 having the small area. The distance between the first routing line RM1 and the neighboring first routing line RM1 may be narrower in the portion overlapping the driving unit 100 than in the portion overlapping the display area DAA in a plan view.

In one or more embodiments, some of the first through holes TSV1 may overlap the driving unit 100 in the thickness direction (e.g., the third direction DR3), and others may not overlap the driving unit 100 in the thickness direction (e.g., the third direction DR3). As for the first routing line RM1 disposed in the first through holes TSV1 that do not overlap the driving unit 100, a portion of the connection line RML (see FIG. 11) may not overlap the driving unit 100. However, the disposition of the first through holes TSV1 may vary according to the location of the layer where the connection lines RML of the first routing lines RM1 are disposed.

According to one or more embodiments, the number of first through holes TSV1 may be equal to the number of the sub-pixels SP1, SP2, and SP3 disposed in the display area DAA. For example, the plurality of sub-pixels SP1, SP2, and SP3 may be arranged along the first direction DR1 and the second direction DR2 in the display area DAA. The first through holes TSV1 may also be arranged along the first direction DR1 and the second direction DR2 and may correspond one-to-one to the respective sub-pixels SP1, SP2, and SP3. The first through holes TSV1 may be formed to respectively overlap the sub-pixels SP1, SP2, and SP3. The number of first routing lines RM1 may be equal to the number of sub-pixels SP1, SP2, and SP3.

The plurality of second through holes TSV2 may be disposed in the through hole area TSA of the display part 200 and may be formed to overlap the signal terminal area TDA of the driving unit 100. The second routing line RM2 connected to the signal terminal STD of the driving unit 100 may be disposed in the second through holes TSV2. Unlike the first through hole TSV1, the second through hole TSV2 may be formed to overlap each signal terminal STD of the driving unit 100. Accordingly, the second routing line RM2 may also be disposed to correspond to and overlap each signal terminal STD. The second routing line RM2 may be a wire that transmits a signal applied from the circuit board 300 to the driving unit 100.

Hereinafter, the structure of the driving circuit layer 120 of the driving unit 100 and the display element layer 230 of the display part 200 will be described in detail with reference to other drawings.

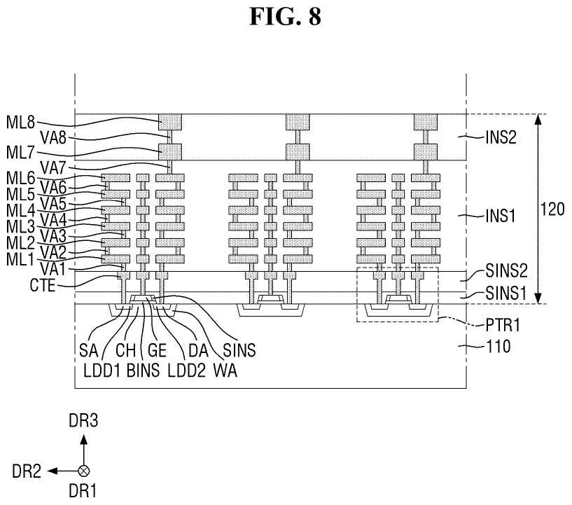

FIG. 8 is a schematic cross-sectional view of a driving unit according to one or more embodiments.

Referring to FIG. 8, the driving unit 100 may include the first single crystal semiconductor substrate 110 and the driving circuit layer 120 disposed thereon.

The first single crystal semiconductor substrate 110 may be a silicon substrate, a germanium substrate, and/or a silicon-germanium substrate. The first single crystal semiconductor substrate 110 may be a substrate doped with a first type impurity. A plurality of well regions WA may be disposed on the top surface of the first single crystal semiconductor substrate 110. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of a first transistor PTR1, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on the side surface of the gate electrode GE. The side insulating layer SINS may be disposed on the lower insulating layer BINS.

Each of the source region SA and the drain region DA may be a region doped with the first type impurity. The gate electrode GE of the first transistor PTR1 may overlap the well region WA in the third direction DR3. The channel region CH may overlap the gate electrode GE in the third direction DR3. The source region SA may be disposed on one side of the gate electrode GE, and the drain region SA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the first transistors PTR1 may increase, so that punch-through and hot carrier phenomena that might be caused by a short channel may be reduced or prevented.

The first single crystal semiconductor substrate 110 may include the plurality of first transistors PTR1 constituting a plurality of circuit elements of the driving unit 100. The first transistors PTR1 formed on the first single crystal semiconductor substrate 110 may constitute the driving circuit portion 400, the gate driver 600, the data driver 700, or the pixel circuit portion 800.

When the driving circuit layer 120 is formed on a silicon wafer substrate, a process of reducing the thickness of the first single crystal semiconductor substrate 110 may be performed. The first single crystal semiconductor substrate 110 may have a thickness smaller than that of a wafer substrate on which a semiconductor process for forming the driving circuit layer 120 is performed. In one or more embodiments, the thickness of the first single crystal semiconductor substrate 110 may be 100 μm or less, for example, in the range of 80 μm to 100 μm.

The driving circuit layer 120 may include a first semiconductor insulating layer SINS1, a second semiconductor insulating layer SINS2, a plurality of contact electrodes CTE, a first interlayer insulating layer INS1, a second interlayer insulating layer INS2, a plurality of conductive layers ML1 to ML8, and a plurality of vias VA1 to VA8. The driving circuit layer 120 may include wires electrically connected to the plurality of first transistors PTR1 included in the first single crystal semiconductor substrate 110.

The first semiconductor insulating layer SINS1 and the second semiconductor insulating layer SINS2 may be disposed on the first single crystal semiconductor substrate 110. The first semiconductor insulating layer SINS1 may be an insulating layer disposed on the first single crystal semiconductor substrate 110, and the second semiconductor insulating layer SINS2 may be an insulating layer disposed on the gate electrode GE of the first transistor PTR1 and the first semiconductor insulating layer SINS1. The first semiconductor insulating layer SINS1 and the second semiconductor insulating layer SINS2 may be formed of a silicon carbon nitride (SiCN) and/or silicon oxide (SiOₓ)-based inorganic layer, but are not limited thereto. In the drawing, the first semiconductor insulating layer SINS1 and the second semiconductor insulating layer SINS2 are each exemplified as a single layer having a suitable thickness (e.g., a predetermined thickness), but are not limited thereto. The first semiconductor insulating layer SINS1 and the second semiconductor insulating layer SINS2 may have a structure in which one or more layers are stacked on top of each other.

The plurality of contact electrodes CTE may be disposed on the first single crystal semiconductor substrate 110. The plurality of contact electrodes CTE may be connected to one of the gate electrodes GE, the source region SA, and/or the drain region DA of each first transistor PTR1 formed on the first single crystal semiconductor substrate 110 through holes penetrating the first and second semiconductor insulating layers SINS1 and SINS2. The plurality of contact electrodes CTE may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The top surfaces of the plurality of contact electrodes CTE may be exposed without being covered by the first and second semiconductor insulating layers SINS1 and SINS2.

The first interlayer insulating layer INS1 may be disposed on the plurality of contact electrodes CTE and the first and second semiconductor insulating layers SINS1 and SINS2. The second interlayer insulating layer INS2 may be disposed on the first interlayer insulating layer INS1. Each of the first interlayer insulating layer INS1 and the second interlayer insulating layer INS2 may be formed of silicon carbonitride (SiCN) and/or a silicon oxide (SiOx)-based inorganic layer, but is not limited thereto. Although it is illustrated in the drawings that each of the first interlayer insulating layer INS1 and the second interlayer insulating layer INS2 is formed as a single layer, the present disclosure is not limited thereto. Each of the first interlayer insulating layer INS1 and the second interlayer insulating layer INS2 may have a structure in which one or more layers are stacked on top of each other, and may be disposed between the plurality of first to eighth conductive layers ML1 to ML8 to be described later.

The first to eighth conductive layers ML1 to ML8 and the first to eighth vias VA1 to VA8 may be electrically connected to the plurality of contact electrodes CTE to form the driving circuit portion 400 and/or the data driver 700 of the driving unit 100. The plurality of first transistors PTR1 formed on the first single crystal semiconductor substrate 110 may be electrically connected to each other through the first to eighth conductive layers ML1 to ML8 and the first to the eighth vias VA1 to VA8, and may form the driving circuit portion 400, and the data driver 700 of the driving unit 100.

The first conductive layer ML1 may be connected to the contact electrode CTE through the first via VA1. The first conductive layer ML1 may be disposed on the contact electrode CTE, and the first via VA1 may be disposed between the first conductive layer ML1 and the contact electrode CTE to be in contact with both of them. The second conductive layer ML2 may be connected to the first conductive layer ML1 through the second via VA2. The second conductive layer ML2 may be disposed on the first conductive layer ML1, and the second via VA2 may be disposed between the first conductive layer ML1 and the second conductive layer ML2 to be in contact with both of them.

The third conductive layer ML3 may be connected to the second conductive layer ML2 through the third via VA3. The fourth conductive layer ML4 may be connected to the third conductive layer ML3 through the fourth via VA4, the fifth conductive layer ML5 may be connected to the fourth conductive layer ML4 through the fifth via VA5, and the sixth conductive layer ML6 may be connected to the fifth conductive layer ML5 through the sixth via VA6. The third conductive layer ML3, the fourth conductive layer ML4, the fifth conductive layer ML5, and the sixth conductive layer ML6 may be sequentially disposed on the second conductive layer ML2, and the third via VA3, the fourth via VA4, the fifth via VA5, and the sixth via VA6 may be disposed between them. The third to sixth vias VA3 to VA6 may be in contact with different metal layers disposed above and below them, respectively. The seventh via VA7 may be disposed on the sixth conductive layer ML6. The seventh via VA7 may be in contact with the seventh conductive layer ML7 and the sixth conductive layer ML6 disposed thereon.

The first to sixth conductive layers ML1 to ML6 and the first to seventh vias VA1 to VA7 may be disposed in the first interlayer insulating layer INS1. The first to sixth conductive layers ML1 to ML6 and the first to seventh vias VA1 to VA7 may constitute a first driving circuit layer disposed in the first interlayer insulating layer INS1 of the driving circuit layer 120.

The seventh conductive layer ML7 may be connected to the sixth conductive layer ML6 through the seventh via VA7. The seventh conductive layer ML7 may be disposed on the first interlayer insulating layer INS1 and the sixth conductive layer ML6, and the seventh via VA7 may be disposed between the sixth conductive layer ML6 and the seventh conductive layer ML7 to be in contact with both of them. The eighth conductive layer ML8 may be connected to the seventh conductive layer ML7 through the eighth via VA8. The eighth conductive layer ML8 is disposed on the seventh conductive layer ML7, and the eighth via VA8 may be disposed between the seventh conductive layer ML7 and the eighth conductive layer ML8 to be in contact with both of them. The top surface of the eighth conductive layer ML8 may be exposed without being covered by the second interlayer insulating layer INS2, and may be electrically connected to the routing lines RM disposed in the display part 200.

The seventh conductive layer ML7, the eighth via VA8, and the eighth conductive layer ML8 may be disposed in the second interlayer insulating layer INS2. The seventh conductive layer ML7, the eighth via VA8, and the eighth conductive layer ML8 may constitute a second driving circuit layer disposed in the second interlayer insulating layer INS2 of the driving circuit layer 120.

In the drawings, although the first to eighth conductive layers ML1 to ML8 and the first to eighth vias VA1 to VA8 are illustrated as being sequentially stacked on top of each other, their layout and connection may be modified in various ways according to the circuits of the driving circuit portion 400, and the data driver 700 of the driving unit 100. The connection structure shown in the drawings is nothing more than an example, and the connection of the driving circuit layer 120 disposed in the driving unit 100 of the display device 10 is not limited thereto. In addition, the driving circuit layer 120 may not necessarily include first to eighth conductive layers ML1 to ML8 and the first to eighth vias VA1 to VA8, and some of these layers may be omitted or more layers may be provided.

The first to eighth conductive layers ML1 to ML8 and the first to eighth vias VA1 to VA8 may be formed of substantially the same material. For example, the first to eighth conductive layers ML1 to ML8 and the first to eighth vias VA1 to VA8 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. In one or more embodiments, the thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å; the thickness of each of the second conductive layer ML2, the third conductive layer ML3, the fourth conductive layer ML4, the fifth conductive layer ML5, and the sixth conductive layer ML6 may be approximately 1440 Å; and the thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

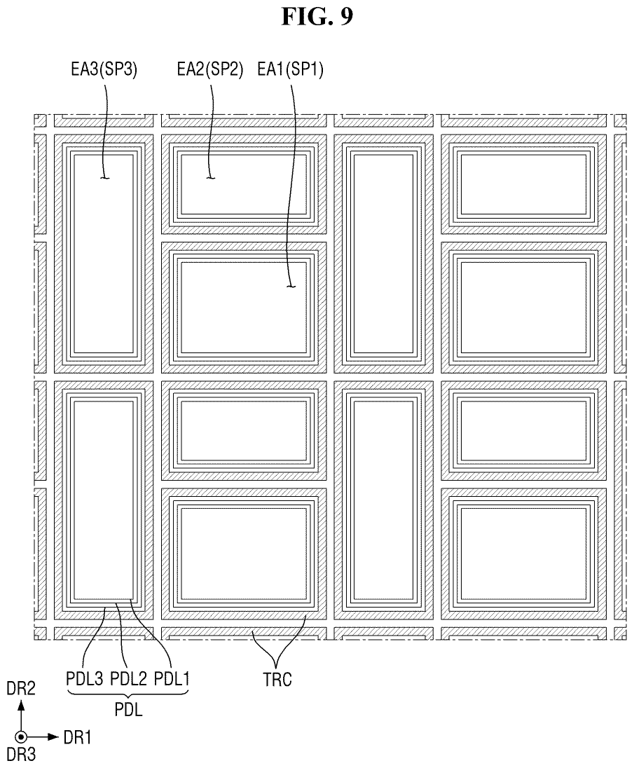

FIG. 9 is a plan view showing a pixel defining layer, and first electrodes and emission areas of a plurality of sub-pixels disposed in a display area of a display part according to one or more embodiments.

Referring to FIG. 9, each of the plurality of pixels PX may include the first sub-pixel SP1, the second sub-pixel SP2, and the third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may have, in a plan view, a quadrilateral shape such as a rectangle, a square, and/or a diamond. For example, the first emission area EA1 may have a rectangular shape, in a plan view, having a long side extending in the first direction DR1 and a short side extending in the second direction DR2. In addition, each of the second emission area EA2 and the third emission area EA3 may have a rectangular shape, in a plan view. The second emission area EA2 may have long side extending in the first direction DR1 and a short side extending in the second direction DR2, whereas the third emission area EA3 may have a short side in the first direction DR1 and a long side in the second direction DR2.

Each of the first emission area EA1, the second emission area EA2, and the third emission area EA3 may be an area defined by a pixel defining layer PDL. For example, each of the first emission area EA1, the second emission area EA2, and the third emission area EA3 may be an area defined by a first pixel defining layer PDL1.

The length of the third emission area EA3 in the first direction DR1 may be smaller than the length of the first emission area EA1 in the first direction DR1, and may be smaller than the length of the second emission area EA2 in the first direction DR1. The length of the first emission area EA1 in the first direction DR1 and the length of the second emission area EA2 in the first direction DR1 may be substantially the same.

In each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different.

Although it is illustrated in the drawing that each of the first emission area EA1, the second emission area EA2, and the third emission area EA3 has a rectangular shape in a plan view, the present disclosure is not limited thereto. For example, each of the first emission area EA1, the second emission area EA2, and the third emission area EA3 may have a polygonal shape other than a quadrilateral shape, a circular shape, and/or an elliptical shape in a plan view.

The first emission area EA1 may emit a first color light, the second emission area EA2 may emit a second color light, and the third emission area EA3 may emit a third color light. Here, the first color may be a red wavelength band, the second color may be a green wavelength band, and the third color may be a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

A first electrode AND (e.g., see FIG. 11) of the light emitting element may have a rectangular shape in a plan view. The planar shape of the first electrode AND of the light emitting element may be different in the first sub-pixel SP1, the second sub-pixel SP2, and the third sub-pixel SP3. For example, the first electrode AND of the first sub-pixel SP1 and the first electrode AND of the second sub-pixel SP2 may have a rectangular planar shape having a long side extending in the first direction DR1 and a short side extending in the second direction DR2. The first electrode AND of the third sub-pixel SP3 may have a rectangular shape, in a plan view, having a short side extending in the first direction DR1 and a long side extending in the second direction DR2. The length of the first electrode AND of the third sub-pixel SP3 in the first direction DR1 may be shorter than the length of the first electrode AND of each of the first sub-pixel SP1 and the second sub-pixel SP2 in the second direction DR2. The length of the first electrode AND of the first sub-pixel SP1 in the second direction DR2 may be longer than the length of the first electrode AND of the second sub-pixel SP2 in the second direction DR2.

The first electrode AND of the light emitting element may be connected to a reflective electrode layer RL (see FIG. 11) via an electrode via VAP. The electrode via VAP may overlap the first pixel defining layer PDL1, a second pixel defining layer PDL2, and a third pixel defining layer PDL3 in the third direction DR3.

At least one trench TRC (e.g., see FIG. 11) may be a structure for cutting off at least one charge generation layer of a light emitting stack IL between the neighboring emission areas EA1, EA2, and EA3. At least one trench TRC may be disposed between the first emission area EA1 and the second emission area EA2, between the first emission area EA1 and the third emission area EA3, and between the second emission area EA2 and the third emission area EA3. More specifically, at least one trench TRC may be disposed between the first electrode AND of the first sub-pixel SP1 and the first electrode AND of the second sub-pixel SP2, between the first electrode AND of the first sub-pixel SP1 and the first electrode AND of the third sub-pixel SP3, and between the first electrode AND of the second sub-pixel SP2 and the first electrode AND of the third sub-pixel SP3.

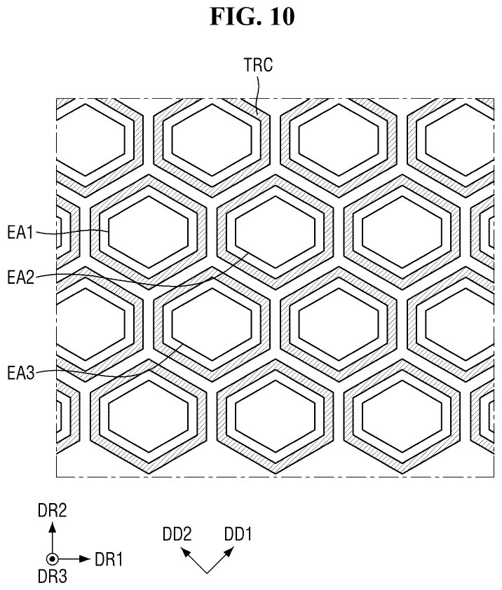

FIG. 10 is a plan view showing a pixel defining layer, and first electrodes and emission areas of a plurality of sub-pixels disposed in a display area of a display part according to one or more embodiments.

Referring to FIG. 10, the embodiment of FIG. 10 is substantially the same as the embodiment of FIG. 9 except that the planar shapes of the first emission area EA1, the second emission area EA2, and the third emission area EA3 are different from those of the embodiment of FIG. 9, description overlapping with the embodiment of FIG. 9 will be omitted.

The first emission area EA1, the second emission area EA2, and the third emission area EA3 may be disposed in a hexagonal structure having a hexagonal shape in a plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

Although it is illustrated in FIGS. 9 and 10 that each of the plurality of pixels PX includes the three emission areas EA1, EA2, and EA3, the present disclosure is not limited thereto. That is, each of the plurality of pixels PX may include four emission areas.

In addition, the layout of the emission areas of the plurality of pixels PX is not limited to that illustrated in the drawing. For example, the emission areas of the plurality of pixels PX may be disposed in a stripe structure in which the emission areas are arranged along the first direction DR1, a PENTILE® arrangement structure in which the emission areas are arranged in a diamond shape, or a hexagonal structure in which the emission areas having, in a plan view, a hexagonal shape are arranged side by side. PENTILE® is a registered trademark of Samsung Display Co., Ltd., Republic of Korea.

FIG. 11 is a cross-sectional view illustrating a part of a display part according to one or more embodiments. FIG. 11 shows a partial cross section of the display area DAA of the display part 200.

Referring to FIG. 11, the display part 200 may include the second single crystal semiconductor substrate 210, a display element layer EML, an encapsulation layer TFE, an adhesive layer ADL, and an optical layer OPL including a color filter layer CFL, a lens LNS, and a filling layer FIL. The display part 200 may further include a cover layer DCL. The display element layer EML, the encapsulation layer TFE, the adhesive layer ADL, the color filter layer CFL, the lens LNS, the filling layer FIL, and the cover layer DCL of the display part 200 may constitute the display element layer 230. In one or more embodiments, the display part 200 may further include a polarizing plate disposed on the cover layer DCL. The connection wiring layer 500 may be disposed between the second single crystal semiconductor substrate 210 and the first single crystal semiconductor substrate 110. Alternatively, the connection wiring layer 500 may be disposed between the display element layer EML and the first single crystal semiconductor substrate 110.

The second single crystal semiconductor substrate 210 may be a silicon substrate, a germanium substrate, and/or a silicon-germanium substrate. The second single crystal semiconductor substrate 210 may be a substrate doped with an impurity. Unlike the first single crystal semiconductor substrate 110, transistors may not be formed on the second single crystal semiconductor substrate 210. The second single crystal semiconductor substrate 210 may serve as a lower substrate on which the display element layer EML is disposed, and may include a connection path in which the routing line RM1 electrically connecting the light emitting element of the display element layer EML to the pixel circuit portion 800 of the driving unit 100 is disposed.

As described above, the first single crystal semiconductor substrate 110 of the driving unit 100 may have a smaller area in a plan view than the second single crystal semiconductor substrate 210 of the display part 200, and small-sized elements may be disposed with a high integration density to reduce power consumption and improve fabrication yield. On the other hand, a process may be performed on the second single crystal semiconductor substrate 210 of the display part 200, which has a relatively large line width and a larger area than the first single crystal semiconductor substrate 110 in a plan view. Unlike the circuit elements formed on the first single crystal semiconductor substrate 110, the elements of the display element layer 230 formed on the second single crystal semiconductor substrate 210 may not require a high integration density. Accordingly, the semiconductor process performed on the first wafer substrate may be performed as a high-cost process having a small line width, and the semiconductor process performed on the second wafer substrate may be performed as a low-cost process having a relatively large line width.

The second single crystal semiconductor substrate 210 may include the plurality of first through holes TSV1 that are spaced (e.g., spaced apart) from each other. The first through hole TSV1 may penetrate the second single crystal semiconductor substrate 210 from the top surface to the bottom surface thereof. The conductive via RVA of the first routing line RM1 may be disposed in the first through hole TSV1. The first through hole TSV1 may form the connection path of the first routing line RM1 that electrically connects the pixel circuit portion 800 of the driving unit 100 to the light emitting element of the display part 200.

In one or more embodiments, the second single crystal semiconductor substrate 210 may include the plurality of second through holes TSV2 formed in the non-display area NA, and conductive vias of the second routing lines RM2 may be disposed in the second through holes TSV2, respectively. The circuit board 300 may be electrically connected to the signal terminal STD of the driving unit 100 via the second routing line RM2.

In one or more embodiments, the first through hole TSV1 of the second single crystal semiconductor substrate 210 may be formed through a through silicon via (TSV) process that forms a hole penetrating a wafer substrate. The display element layer 230 may be electrically connected to the driving unit 100 through the routing line RM1 and the through hole TSV1 formed in the second single crystal semiconductor substrate 210, without a separate wire.

A process of reducing the thickness of the second single crystal semiconductor substrate 210 may be performed after the driving unit 100 is bonded onto the silicon wafer substrate. The second single crystal semiconductor substrate 210 may have a thickness greater than that of the wafer substrate on which a process for forming conductive layers is performed. In one or more embodiments, the thickness of the second single crystal semiconductor substrate 210 may be 100 μm or less, for example, in the range of 80 μm to 100 μm.

The connection wiring layer 500 may be disposed on the bottom surface of the second single crystal semiconductor substrate 210. The connection wiring layer 500 may include an interlayer insulating layer RINS and the plurality of connection lines RML.

The interlayer insulating layer RINS may be disposed on the bottom surface of the second single crystal semiconductor substrate 210. The interlayer insulating layer RINS may be formed of a silicon carbon nitride (SiCN) and/or silicon oxide (SiOx)-based inorganic layer, but is not limited thereto. In the drawings, the interlayer insulating layer RINS is illustrated as being formed as a single layer. However, the present disclosure is not limited thereto, and the interlayer insulating layer RINS may have a structure in which one or more layers are stacked on top of each other, and these layers may be disposed between the connection lines RML.

The connection lines RML may constitute the routing lines RM1 and RM2 together with the conductive via RVA. The connection line RML may include one or more conductive layers, and one or more vias connecting them to each other. The connection and the structure of the connection lines RML may be the same as those of the plurality of conductive layers ML1 to ML8 and the plurality of vias VA1 to VA8 described above. The connection line RML may be connected to the light emitting elements of the sub-pixels SP1, SP2, and SP3 or the circuit board 300 through the conductive vias RVA disposed in the through holes TSV1 and TSV2 of the second single crystal semiconductor substrate 210 and may electrically connect them to the driving circuit layer 120 of the driving unit 100.

The conductive via RVA of the first routing line RM1 may be disposed in the first through hole TSV1. The conductive via RVA of the first routing line RM1 may be disposed in the first through hole TSV1 from the bottom surface of the reflective electrode layer RL, which will be described later, to the bottom surface of the second single crystal semiconductor substrate 210. The conductive via RVA may be electrically connected to the first electrode AND disposed in each of the sub-pixels SP1, SP2, and SP3 via the reflective electrode layer RL. The conductive via RVA may be connected to each of the reflective electrode layer RL and the connection line RML, and the connection line RML may be connected to the pixel circuit portion 800. The connection line RML may be a wire illustrated on the rear surface of the display part 200 in FIG. 7. The first routing line RM1 may connect the light emitting element of each of the sub-pixels SP1, SP2, and SP3 to the pixel circuit portion 800 of the driving unit 100.

The display element layer 230 may be disposed on the second single crystal semiconductor substrate 210. The display element layer 230 may include the display element layer EML, the encapsulation layer TFE, the adhesive layer ADL, the optical layer OPL, and the cover layer DCL. The display element layer 230 may include light emitting elements electrically connected to the driving unit 100 and emit light.

The display element layer EML may be disposed on the second single crystal semiconductor substrate 210. The display element layer EML may include light emitting elements having the reflective electrode layer RL, interlayer insulating layers INS3 and INS4, the electrode via VAP, the first electrode AND, the light emitting stack IL, and a second electrode CAT, the pixel defining layer PDL, and the plurality of trenches TRC.

The reflective electrode layer RL may be disposed on the second single crystal semiconductor substrate 210. The reflective electrode layer RL may include at least one reflective electrode RL1, RL2, RL3, and/or RL4. For example, the reflective electrode layer RL may include first to fourth reflective electrodes RL1, RL2, RL3, and/or RL4 as shown in FIG. 11.

Each of the first reflective electrodes RL1 may be disposed on the second single crystal semiconductor substrate 210 and may be connected to the conductive via RVA disposed in the first through hole TSV1. The first reflective electrodes RL1 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first reflective electrodes RL1 may include titanium nitride (TiN).

Each of the second reflective electrodes RL2 may be disposed on the first reflective electrode RL1. The second reflective electrodes RL2 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the second reflective electrodes RL2 may include aluminum (Al).

Each of the third reflective electrodes RL3 may be disposed on the second reflective electrode RL2. The third reflective electrodes RL3 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the third reflective electrodes RL3 may include titanium nitride (TiN).

The fourth reflective electrodes RL4 may be respectively disposed on the third reflective electrodes RL3. The fourth reflective electrodes RL4 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the fourth reflective electrodes RL4 may include titanium (Ti).

Because the second reflective electrode RL2 is an electrode that substantially reflects light from the light emitting elements, in one or more embodiments, the thickness of the second reflective electrode RL2 may be greater than the thickness of each of the first reflective electrode RL1, the third reflective electrode RL3, and the fourth reflective electrode RL4. For example, in one or more embodiments, the thickness of each of the first reflective electrode RL1, the third reflective electrode RL3, and the fourth reflective electrode RL4 may be approximately 100 Å, and the thickness of the second reflective electrode RL2 may be 850 Å. In one or more other embodiments, because the fourth reflective electrode RL4 is an electrode that substantially reflects light from the light emitting elements, the thickness of the fourth reflective electrode RL4 may be greater than the thickness of each of the first reflective electrode RL1, the second reflective electrode RL2, and the third reflective electrode RL3. For example, in one or more embodiments, the thickness of each of the first reflective electrode RL1, the second reflective electrode RL2, and the third reflective electrode RL3 may be approximately 100 Å, and the thickness of the fourth reflective electrode RL4 may be 850 Å.

The third interlayer insulating layer INS3 may be disposed on the second single crystal semiconductor substrate 210. The third interlayer insulating layer INS3 may be disposed between the reflective electrode layers RL adjacent to each other. The third interlayer insulating layer INS3 may be disposed on the reflective electrode layer RL in the first sub-pixel SP1. The third interlayer insulating layer INS3 may be formed of a silicon oxide (SiOx)-based inorganic layer, but is not limited thereto.

The fourth interlayer insulating layer INS4 may be disposed on the third interlayer insulating layer INS3 and the reflective electrode layer RL. The fourth interlayer insulating layer INS4 may be formed of a silicon oxide (SiOx)-based inorganic layer, but is not limited thereto.

In at least one of the first sub-pixel SP1, the second sub-pixel SP2, or the third sub-pixel SP3, the third interlayer insulating layer INS3 and the fourth interlayer insulating layer INS4 may not be disposed under the first electrode AND in consideration of the resonance distance of the light emitted from the light emitting elements.

For example, the first electrode AND of the third sub-pixel SP3 may be directly disposed on the fourth reflective electrode RL4, and the first electrode AND of the third sub-pixel SP3 may not overlap the third interlayer insulating layer INS3 and the fourth interlayer insulating layer INS4. The first electrode AND of the second sub-pixel SP2 may be disposed on the fourth interlayer insulating layer INS4, and the fourth interlayer insulating layer INS4 may be directly disposed on the fourth reflective electrode RL4. That is, the first electrode AND of the second sub-pixel SP2 may not overlap the third interlayer insulating layer INS3. The first electrode AND of the first sub-pixel SP1 may be disposed on the fourth interlayer insulating layer INS4, and may overlap the third interlayer insulating layer INS3.

In one or more embodiments, the distance between the first electrode AND and the reflective electrode layer RL may be different in the first sub-pixel SP1, the second sub-pixel SP2, and the third sub-pixel SP3. In order to adjust the distance from the reflective electrode layer RL to the second electrode CAT according to the main wavelength of the light emitted from each of the first sub-pixel SP1, the second sub-pixel SP2, and the third sub-pixel SP3, the presence or absence of the third interlayer insulating layer INS3 and the fourth interlayer insulating layer INS4 may be set in each of the first sub-pixel SP1, the second sub-pixel SP2, and the third sub-pixel SP3. For example, in FIG. 11, the distance between the first electrode AND and the reflective electrode layer RL in the first sub-pixel SP1 may be greater than the distance between the first electrode AND and the reflective electrode layer RL in the second sub-pixel SP2 and the distance between the first electrode AND and the reflective electrode layer RL in the third sub-pixel SP3, and the distance between the first electrode AND and the reflective electrode layer RL in the second sub-pixel SP2 may be greater than the distance between the first electrode AND and the reflective electrode layer RL in the third sub-pixel SP3. However, the present disclosure is not limited thereto. The distance between the first electrode AND and the reflective electrode layer RL in each of the sub-pixels SP1, SP2, and SP3 may be variously modified and designed.

Each of the electrode vias VAP may be connected to the fourth reflective electrode RL4 exposed through the third interlayer insulating layer INS3 and/or the fourth interlayer insulating layer INS4 in the first sub-pixel SP1 and the second sub-pixel SP2. The electrode vias VAP may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The thickness of the electrode via VAP in the second sub-pixel SP2 may be smaller than the thickness of the electrode via VAP in the first sub-pixel SP1.

The first electrode AND of each of the light emitting elements is disposed on the fourth interlayer insulating layer INS4 or the reflective electrode layer RL and may be connected to the electrode via VAP. The first electrode AND of each of the light emitting elements LE may be connected to the pixel circuit portion 800 through the electrode via VAP, the first to fourth reflective electrodes RL1 to RL4, and the first routing line RM1. The first electrode AND of each of the light emitting elements may be formed of one of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first electrode AND of each of the light emitting elements may be titanium nitride (TiN).

The pixel defining layer PDL may be disposed on a portion of the first electrode AND of each of the light emitting elements. The pixel defining layer PDL may cover the edge of the first electrode AND of each of the light emitting elements. The pixel defining layer PDL may serve to partition the first emission areas EA1, the second emission areas EA2, and the third emission areas EA3.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining layer PDL may include first to third pixel defining layers PDL1, PDL2, and PDL3. The first pixel defining layer PDL1 may be disposed on the edge of the first electrode AND of each of the light emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOx)-based inorganic layer, but are not limited thereto. The first pixel defining layer PDL1, the second pixel defining layer PDL2, and the third pixel defining layer PDL3 may each have a thickness of about 500 Å.

When the first pixel defining layer PDL1, the second pixel defining layer PDL2, and the third pixel defining layer PDL3 are formed as one pixel defining layer, the height of the one pixel defining layer increases, so that a first inorganic encapsulation layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

In order to prevent the first inorganic encapsulation layer TFE1 from being cut off due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

Each of the plurality of trenches TRC may penetrate the first pixel defining layer PDL1, the second pixel defining layer PDL2, and the third pixel defining layer PDL3. In each of the plurality of trenches TRC, a portion of the third interlayer insulating layer INS3 may be dug and the fourth interlayer insulating layer INS4 may be penetrated.

At least one trench TRC may be disposed between adjacent sub-pixels SP1, SP2, and SP3. FIG. 11 illustrates that two trenches TRC are disposed between the adjacent sub-pixels SP1, SP2, and SP3, but the present disclosure is not limited thereto.

The light emitting stack IL may include a plurality of light emitting stacks IL1, IL2, and IL3. It is illustrated in the drawing that the light emitting stack IL has a three-tandem structure including a first light emitting stack IL1, a second light emitting stack IL2, and a third light emitting stack IL3, but the present disclosure is not limited thereto. For example, the light emitting stack IL may have a two-tandem structure including two stacks.

In the three-tandem structure, the light emitting stack IL may have a tandem structure including the plurality of light emitting stacks IL1, IL2, and IL3 that emit different lights. For example, the light emitting stack IL may include the first light emitting stack IL1 that emits the first color light, the second light emitting stack IL2 that emits the third color light, and the third light emitting stack IL3 that emits the second color light. The first light emitting stack IL1, the second light emitting stack IL2, and the third light emitting stack IL3 may be sequentially stacked.

The first light emitting stack IL1 may have a structure in which a first hole transport layer, a first organic light emitting layer that emits the first color light, and a first electron transport layer are sequentially stacked. The second light emitting stack IL2 may have a structure in which a second hole transport layer, a second organic light emitting layer that emits the third color light, and a second electron transport layer are sequentially stacked. The third light emitting stack IL3 may have a structure in which a third hole transport layer, a third organic light emitting layer that emits the second color light, and a third electron transport layer are sequentially stacked.

A first charge generation layer for supplying charges to the second light emitting stack IL2 and supplying electrons to the first light emitting stack IL1 may be disposed between the first light emitting stack IL1 and the second light emitting stack IL2. The first charge generation layer may include an N-type charge generation layer that supplies electrons to the first light emitting stack IL1 and a P-type charge generation layer that supplies holes to the second light emitting stack IL2. The N-type charge generation layer may include a dopant of a metal material.

A first charge generation layer for supplying charges to the third light emitting stack IL3 and supplying electrons to the second light emitting stack IL2 may be disposed between the second light emitting stack IL2, and the third light emitting stack IL3. The second charge generation layer may include an N-type charge generation layer that supplies electrons to the second light emitting stack IL2 and a P-type charge generation layer that supplies holes to the third light emitting stack IL3.

The first light emitting stack IL1 may be disposed on the first electrodes AND and the pixel defining layer PDL, and may be disposed on the bottom surface of each trench TRC. Due to the trench TRC, the first light emitting stack IL1 may be cut off between adjacent sub-pixels SP1, SP2, and SP3. The second light emitting stack IL2 may be disposed on the first light emitting stack IL1. Due to the trench TRC, the second light emitting stack IL2 may be cut off between adjacent sub-pixels SP1, SP2, and SP3. A void or an empty space may be disposed between the first light emitting stack IL1 and the second light emitting stack IL2. The third light emitting stack IL3 may be disposed on the second light emitting stack IL2. The third light emitting stack IL3 is not cut off by the trench TRC and may be disposed to cover the second light emitting stack IL2 in each of the trenches TRC. That is, in the three-tandem structure, each of the plurality of trenches TRC may be a structure for cutting off the first to second light emitting stacks IL1 and IL2, the first charge generation layer, and the second charge generation layer of the display element layer EML between the sub-pixels SP1, SP2, and SP3 adjacent to each other. In addition, in the two-tandem structure, each of the trenches TRC may be a structure for cutting off the charge generation layer disposed between a lower intermediate layer and an upper intermediate layer, and the lower intermediate layer.

In order to stably cut off the first and second light emitting stacks IL1 and IL2 of the display element layer EML between adjacent sub-pixels SP1, SP2, and SP3, the height of each of the plurality of trenches TRC may be greater than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3. In order to cut off the first to third light emitting stacks IL1, IL2, and IL3 of the display element layer EML between the neighboring sub-pixels SP1, SP2, and SP3, another structure may exist instead of the trench TRC. For example, instead of the trench TRC, a reverse tapered partition wall may be disposed on the pixel defining layer PDL.

The number of the light emitting stacks IL1, IL2, and IL3 that emit different lights is not limited to that shown in the drawing. For example, the light emitting stack IL may include two intermediate layers. In this case, one of the two intermediate layers may be substantially the same as the first light emitting stack IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be disposed between the two intermediate layers.

In addition, FIG. 11 illustrates that the first to third light emitting stacks IL1, IL2, and IL3 are all disposed in the first emission area EA1, the second emission area EA2, and the third emission area EA3, but the present disclosure is not limited thereto. For example, the first light emitting stack IL1 may be disposed in the first emission area EA1, and may not be disposed in the second emission area EA2 and the third emission area EA3. Furthermore, the second light emitting stack IL2 may be disposed in the second emission area EA2 and may not be disposed in the first emission area EA1 and the third emission area EA3. Further, the third light emitting stack IL3 may be disposed in the third emission area EA3 and may not be disposed in the first emission area EA1 and the second emission area EA2. In this case, first to third color filters CF1, CF2, and CF3 of the optical layer OPL may be omitted.

The second electrode CAT may be disposed on the third light emitting stack IL3. The second electrode CAT may be disposed on the third light emitting stack IL3 in each of the plurality of trenches TRC. The second electrode CAT may be formed of a transparent conductive material (TCO) such as ITO and/or IZO that can transmit light or a semi-transmissive conductive material such as magnesium (Mg), silver (Ag), and/or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic encapsulation layer TFE1 and TFE3 to prevent oxygen and/or moisture from permeating into the display element layer EML. In addition, the encapsulation layer TFE may include at least one organic layer to protect the display element layer EML from foreign substances such as dust. For example, the encapsulation layer TFE may include the first inorganic encapsulation layer TFE1, an organic encapsulation layer TFE2, and a second inorganic encapsulation layer TFE3.

The first inorganic encapsulation layer TFE1 may be disposed on the second electrode CAT, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be formed of multiple layers in which one or more inorganic layers of silicon nitride (SiNₓ), silicon oxynitride (SiOₓN_{y}), silicon oxide (SiOₓ), titanium oxide (TiOₓ), and/or aluminum oxide (AlOₓ) layers are alternately stacked. The organic encapsulation layer TFE2 may be a monomer. Alternatively, the organic encapsulation layer TFE2 may be an organic layer such as acryl resin, epoxy resin, phenolic resin, polyamide resin, polyimide resin, and/or the like.

The adhesive layer ADL may be disposed on the encapsulation layer TFE. The adhesive layer ADL may be a layer for bonding the encapsulation layer TFE to a layer disposed thereon. The adhesive layer ADL may be a double-sided adhesive member. In addition, the adhesive layer ADL may be a transparent adhesive member such as a transparent adhesive and/or a transparent adhesive resin.

The optical layer OPL may include the color filter layer CFL, the plurality of lenses LNS, and a filling layer FIL. The color filter layer CFL may include the first to third color filters CF1, CF2, and CF3. The first to third color filters CF1, CF2, and CF3 may be disposed on the adhesive layer ADL.

The first color filter CF1 may overlap the first emission area EA1. The first color filter CF1 may transmit the first color light, i.e., a red wavelength band. The red wavelength band may be approximately 600 nm to 750 nm. The first color filter CF1 may transmit the first color light from among light emitted from the first emission area EA1.

The second color filter CF2 may overlap the second emission area EA2. The second color filter CF2 may transmit the second color light, i.e., a green wavelength band. The green wavelength band may be approximately 480 nm to 560 nm. The second color filter CF2 may transmit the second color light from among light emitted from the second emission area EA2.

The third color filter CF3 may overlap the third emission area EA3. The third color filter CF3 may transmit the third color light, i.e., a blue wavelength band. The blue wavelength band may be approximately 370 nm to 460 nm. The third color filter CF3 may transmit the third color light from among light emitted from the third emission area EA3.

The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a suitable refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic layer such as acrylic resin, epoxy resin, phenolic resin, polyamide resin, and/or polyimide resin.

The cover layer DCL may be disposed on the filling layer FIL. The cover layer DCL may be a glass substrate or a polymer resin. When the cover layer DCL is a glass substrate, it may be attached onto the filling layer FIL. In this case, the filling layer FIL may serve to bond the cover layer DCL. When the cover layer DCL is a glass substrate, it may serve as an encapsulation substrate. When the cover layer DCL is a polymer resin, it may be directly applied onto the filling layer FIL.

In one or more embodiments, the display part 200 may further include a polarizing plate disposed on the cover layer DCL. The polarizing plate may be disposed on one surface of the cover layer DCL. The polarizing plate may be a structure for preventing visibility degradation caused by reflection of external light. The polarizing plate may include a linear polarizing plate and/or a phase retardation film. For example, the phase retardation film may be a λ/4 plate (e.g., quarter-wave plate), but is not limited thereto. However, when visibility degradation caused by reflection of external light is sufficiently overcome by the first to third color filters CF1, CF2, and CF3, the polarizing plate may be omitted.

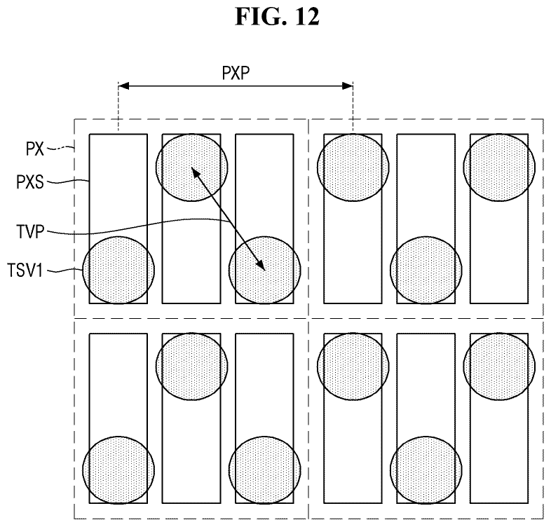

FIG. 12 is a plan view showing a schematic disposition of pixel areas and through holes disposed in a display area of a display part according to one or more embodiments.

Referring to FIG. 12, each pixel PX of the display part 200 may include three sub-pixel portions PXS corresponding to the respective sub-pixels SP1, SP2, and SP3. The sub-pixel portion PXS may be one of three evenly divided regions from one pixel PX. The sub-pixel portion PXS may be a region allocated to each of the sub-pixels SP1, SP2, and SP3 included in one pixel PX, but may not be the same as the sub-pixel SP1, SP2, SP3. As described above, in the display part 200, the shape and disposition of the sub-pixels SP1, SP2 and SP3 or the emission areas EA1, EA2, and EA3 may vary according to the disposition and shape of the first electrode AND of the light emitting element and/or the trench TRC of the pixel defining layer PDL in a plan view. The shape and disposition of the sub-pixels SP1, SP2, and SP3 may be designed with respect to the three sub-pixel portions PXS included in one pixel PX, and the routing lines RM1 disposed with respect to the sub-pixel portions PXS may be electrically connected to the sub-pixels SP1, SP2, and SP3.

For example, in the embodiment of FIG. 12, three sub-pixels SP1, SP2, and SP3 and three emission areas EA1, EA2, and EA3 may be disposed adjacent to each other in the first direction DR1 and the second direction DR2. Although the arrangement of the three sub-pixel portions PXS is different from the arrangement of the three sub-pixels SP1, SP2, and SP3, at least a portion of each sub-pixel SP1, SP2, SP3 may overlap the area of the sub-pixel portion PXS. When one sub-pixel SP1, SP2, SP3 is designed with respect to the sub-pixel portion PXS and an overlapping area thereof exists, the first electrode AND and/or the reflective electrodes RL1, RL2, RL3, and RL4 may be disposed to cover the overlapping area. Accordingly, the routing lines RM1 designed with respect to the sub-pixel portions PXS may be electrically connected to the light emitting elements.

In the display area DAA, the sub-pixels SP1, SP2, and SP3 may not necessarily have an even arrangement according to the type of light emitted from each light emitting element or the type of light displayed from the emission areas EA1, EA2, and EA3. On the other hand, the sub-pixel portion PXS is one of the evenly divided regions from each pixel PX, and may have a constant arrangement throughout the display area DAA. Accordingly, when each of the sub-pixels SP1, SP2, and SP3 is connected to another element, for example, the pixel circuit portion 800 of the driving unit 100, the disposition of the first through holes TSV1 may be easily designed based on the arrangement of the sub-pixel portions PXS rather than the arrangement of the sub-pixels SP1, SP2, and SP3.

According to one or more embodiments, the plurality of first through holes TSV1 formed in the second single crystal semiconductor substrate 210 in the display area DAA of the display part 200 may be disposed to respectively correspond to the different sub-pixel portions PXS in one pixel PX, and the first through holes TSV1 respectively corresponding to the neighboring sub-pixel portions PXS may be spaced from each other in a diagonal direction. In the display area DAA of the display part 200, the first through holes TSV1 may be disposed in the same number as the number of sub-pixels SP1, SP2, and SP3 or the number of sub-pixel portions PXS. Three first through holes TSV1 may be disposed in one pixel PX, and a gap TVP between the first through holes TSV1 may vary according to the gap between the neighboring pixels PX and the diameter of the first through hole TSV1.

For example, when the gap between adjacent first through holes TSV1 is greater than the gap PXP between the same sub-pixel portions PXS in the neighboring pixels PX, the three first through holes TSV1 may not be disposed to correspond to the sub-pixel portions PXS in one pixel PX. In this case, a separate routing line may be required to connect the first through holes TSV1 or the conductive vias RVA disposed in the first through holes TSV1 to the sub-pixels SP1, SP2, and SP3. That is, when the disposition of the first through holes TSV1 and the gap TVP between them are designed according to the gap PXP between the same sub-pixel portions PXS in the neighboring pixels PX of the display part 200, three first through holes TSV1 may be disposed to correspond to different sub-pixel portions PXS in each pixel PX. Accordingly, the non-display area NA or dead space of the display part 200 may be reduced, and a micro-display device 10 may be implemented.

In one or more embodiments, the plurality of first through holes TSV1 disposed in one pixel PX may be spaced (e.g., spaced apart) from each other in the diagonal direction, and the gap TVP between the centers of the first through holes TSV1 that are spaced (e.g., spaced apart) in the diagonal direction may be 62% or less, or 61.0328% or less of the gap PXP between the same sub-pixel portions PXS in the neighboring pixels PX. For example, in an embodiment where the gap PXP between the same sub-pixel portions PXS in the neighboring pixels PX is 8.47 μm, the gap TVP between the centers of the first through holes TSV1 that are spaced (e.g., spaced apart) in the diagonal direction may be 5.16 μm or less. However, if the gap between the first through holes TSV1 is too small, interference may occur between the conductive vias RVA disposed in the respective first through holes TSV1. Therefore, a minimum separation distance may be maintained therebetween. For example, in an embodiment where the diameter of the first through hole TSV1 is approximately 3 μm, the gap TVP between the centers of the first through holes TSV1 that are spaced (e.g., spaced apart) in the diagonal direction may be greater than 3 μm.

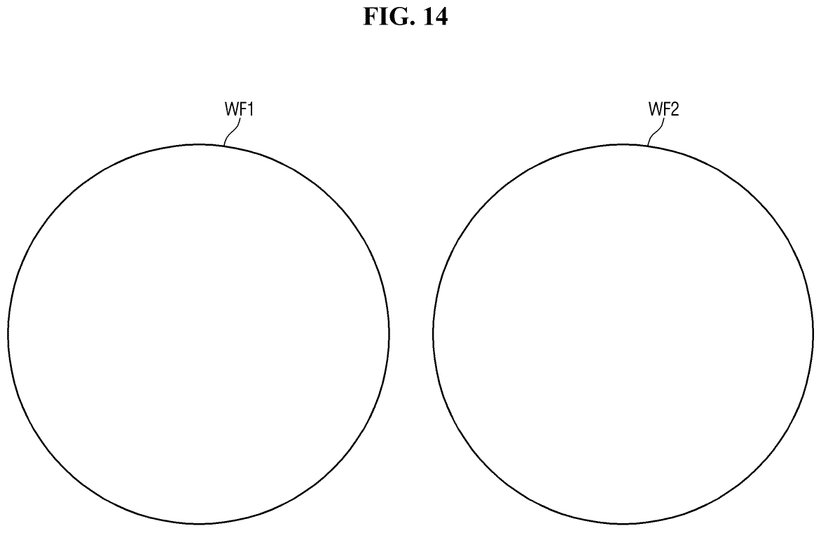

In the display device 10 according to one or more embodiments, optimized fabrication processes for the elements of the driving unit 100 and for the light emitting elements of the display part 200 may be different from each other. In consideration of this, they may be formed on different wafers through separate processes capable of increasing fabrication yields. In particular, because the process of forming the driving circuit layer 120 included in the driving unit 100 of the display device 10 is performed as a micro semiconductor process, the yield per unit area of the first wafer substrate WF1 (e.g., see FIG. 14) may be improved. In addition, the process of forming the display part 200 of the display device 10 may be desirable because the space occupied by unnecessary elements other than the light emitting element may be reduced or minimized and a display device with a high resolution per unit area may be implemented.

Further, the display device 10 may have a structure in which the driving unit 100 and the display part 200, which include different single crystal semiconductor substrates, are connected via the routing lines RM1 and RM2. The through holes TSV1, in which the conductive vias RVA of the routing lines RM1 and RM2 are disposed, may be disposed to correspond one-to-one to the sub-pixels SP1, SP2, and SP3 in each pixel PX of the display part 200. Because the first through holes TSV1 may all be disposed in the pixel PX, a separate space or dead space for connecting the sub-pixels SP1, SP2, and SP3 to the routing lines RM1 and RM2 may be reduced.

Hereinafter, a method for fabrication of the display device 10 will be described with reference to other drawings.

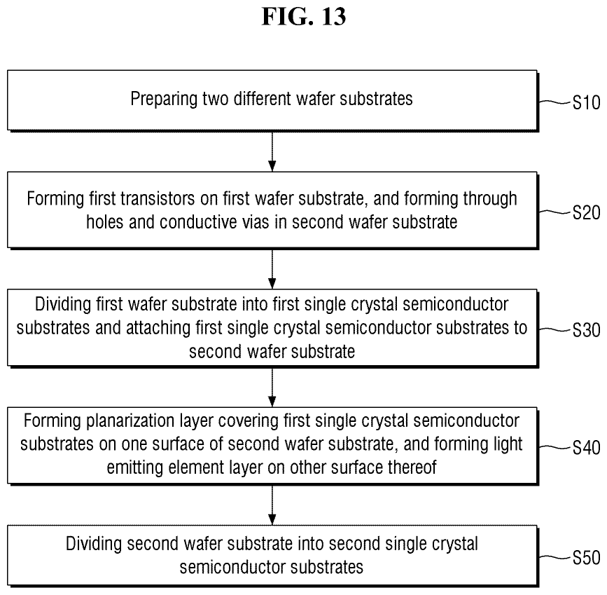

FIG. 13 is a flowchart illustrating a method for fabrication of a display device according to one or more embodiments.

Referring to FIG. 13, a method for fabrication of the display device 10 according to one or more embodiments may include preparing two different wafer substrates (step S10), forming first transistors on a first wafer substrate and forming through holes and conductive vias in a second wafer substrate (step S20), dividing the first wafer substrate into first single crystal semiconductor substrates and attaching the first single crystal semiconductor substrates to the second wafer substrate (step S30), forming a planarization layer that covers the first single crystal semiconductor substrates on one surface of the second wafer substrate and forming a light emitting element layer on the other surface thereof (step S40), and dividing the second wafer substrate into second single crystal semiconductor substrates (step S50).

The method for fabrication of the display device 10 may include performing processes suitable for forming the components of the display device 10 respectively on two different wafer substrates, and bonding them to each other. The driving unit 100 including the driving circuit layer 120 may be fabricated by forming fine-sized elements on the first wafer substrate and may be bonded to the second wafer substrate, and then the display element layer 230 including the display element layer EML may be formed to fabricate the display part 200. Accordingly, on the first wafer substrate, fine elements may be formed at a high integration density, thereby improving fabrication yield and reducing fabrication cost, and on the second wafer substrate, circuits other than the light emitting elements are not disposed, thereby reducing an unnecessary area and enabling the implementation of a high-resolution display device.

FIGS. 14-19 are diagrams sequentially showing a fabrication process of a display device according to one or more embodiments. FIGS. 14-19 schematically show a process in which two different wafer substrates WF1 and WF2 are bonded to each other and divided.

Referring to FIG. 14, a first wafer substrate WF1 and a second wafer substrate WF2 are prepared (step S10). Each of the first wafer substrate WF1 and the second wafer substrate WF2 may be a silicon substrate, a germanium substrate, and/or a silicon-germanium substrate. The first single crystal semiconductor substrate 110 and the second single crystal semiconductor substrate 210 may be substrates doped with the first type impurity. A plurality of well regions may be disposed on the top surface of the first single crystal semiconductor substrate 110. They may be mother substrates of the first single crystal semiconductor substrate 110 and the second single crystal semiconductor substrate 210 of the display device 10.

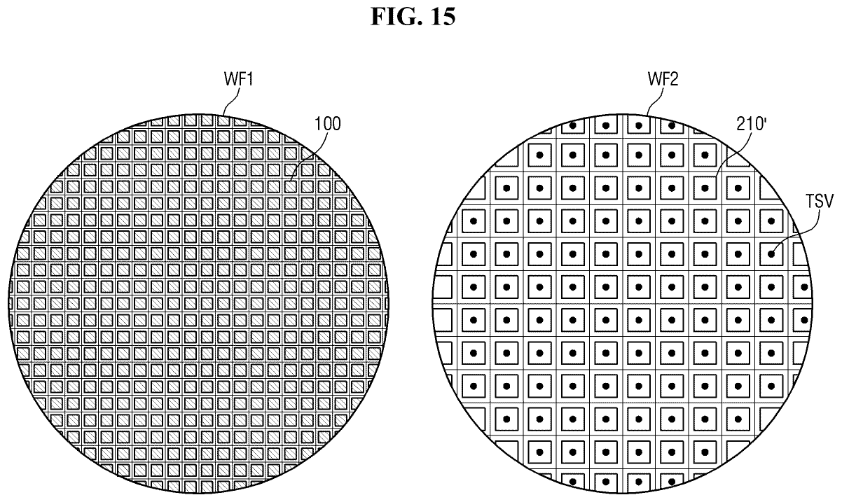

Referring to FIG. 15, the driving unit 100 is fabricated by forming the plurality of first transistors PTR1 and the driving circuit layer 120 on one surface of the first wafer substrate WF1. The plurality of through holes TSV penetrating the second wafer substrate WF2 and the conductive vias RVA disposed therein are formed in the second wafer substrate WF2 to form a temporary single crystal semiconductor substrate 210′.

The process of forming the plurality of first transistors PTR1 and the driving circuit layer 120 on the first wafer substrate WF1 may be a micro semiconductor process. On the other hand, the process of forming the through hole TSV on the second wafer substrate WF2 may be a process having a larger line width than the semiconductor process performed on the first wafer substrate WF1. Although the first wafer substrate WF1 and the second wafer substrate WF2 have the same area, the driving unit 100 and the temporary single crystal semiconductor substrate 210′ formed in this process may have different areas. Accordingly, the number of the driving units 100 formed on the first wafer substrate WF1 may be greater than the number of the temporary single crystal semiconductor substrates 210′ formed on the second wafer substrate WF2. The process of fabricating the driving unit 100 on the first wafer substrate WF1 is an expensive semiconductor process, but may be desirable because of having a relatively high yield.

In the method for fabrication of the display device 10, a display device in which the pixel circuit portion 800 necessary for driving the light emitting element of the display part 200 is disposed in the driving circuit layer 120 of the driving unit 100 may be fabricated, and in a process of forming the driving circuit layer 120 on the first wafer substrate WF1, the driving circuit layer 120 may include the pixel circuit portion 800 in addition to the driving circuit portion 400, the gate driver 600, and the data driver 700.

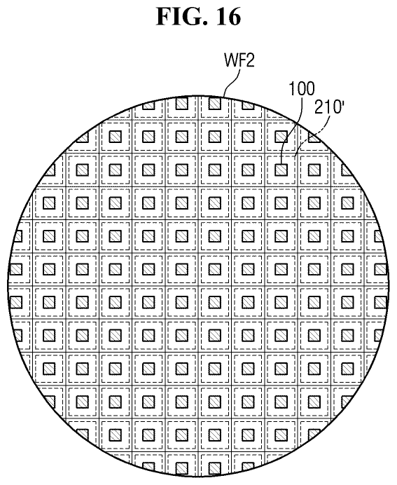

Next, referring to FIG. 16, the first wafer substrate WF1 is divided into a plurality of first single crystal semiconductor substrates 110, and the first single crystal semiconductor substrates 110 are attached to the bottom surface of the second wafer substrate WF2. The first wafer substrate WF1 may be divided into the plurality of first single crystal semiconductor substrates 110 on which the driving circuit layers 120 are formed. In one or more embodiments, the driving circuit layer 120 disposed on the first single crystal semiconductor substrate 110 may be bonded to the bottom surface of the temporary single crystal semiconductor substrate 210′. The process of bonding the first single crystal semiconductor substrate 110 to the bottom surface of the second wafer substrate WF2 may not be a bonding between two different wafer substrates, but rather a process of separating the first single crystal semiconductor substrate 110 from the first wafer substrate WF1 and then bonding it to the second wafer substrate WF2. The plurality of first single crystal semiconductor substrates 110 may be bonded correspondingly to the plurality of temporary single crystal semiconductor substrates 210′ formed on the second wafer substrate WF2.

The process of bonding the first single crystal semiconductor substrate 110 to the second wafer substrate WF2 may be performed under a higher temperature condition than a process of forming the light emitting element layer to be described later. According to one or more embodiments, the process of bonding the first single crystal semiconductor substrate 110 to the second wafer substrate WF2 may be performed prior to the process of forming the display element layer EML including the light emitting element on the second wafer substrate WF2. The method for fabrication of the display device 10 may not be a method of respectively fabricating the driving unit 100 including the first single crystal semiconductor substrate 110 and the display part 200 including the second single crystal semiconductor substrate 210, and bonding them to each other. The method for fabrication of the display device 10 may involve a process of dividing the first wafer substrate WF1 into the driving units 100 and bonding them to the second wafer substrate WF2 on which the light emitting elements are not formed.

In one or more embodiments, prior to performing the bonding process of FIG. 16, the connection wiring layer 500 may be formed on the temporary single crystal semiconductor substrate 210′. The connection wiring layer 500 may be formed on the bottom surface of the second wafer substrate WF2, and the first single crystal semiconductor substrate 110 may be attached to the bottom surface of the second wafer substrate WF2 on which the connection wiring layer 500 is formed. Accordingly, the driving circuit layer 120 formed on the first single crystal semiconductor substrate 110 may be electrically connected to the connection wiring layer 500. However, the present disclosure is not limited thereto. The first single crystal semiconductor substrate 110 may be attached to the top surface of the second wafer substrate WF2 on which the connection wiring layer 500 is not formed. In this case, a planarization layer 910 to be described later may be formed on the top surface of the second wafer substrate WF2, and the display element layer EML may be formed on the top surface of the connection wiring layer 500 or on the bottom surface of the second wafer substrate WF2.

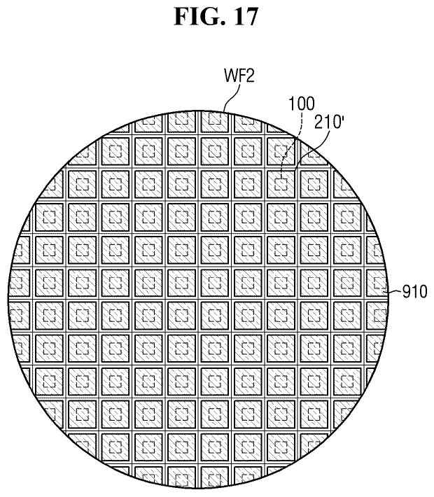

Next, referring to FIG. 17, the planarization layer 910 is formed on the bottom surface of the second wafer substrate WF2. The planarization layer 910 may flatten a step caused by the plurality of first single crystal semiconductor substrates 110 disposed on the bottom surface of the second wafer substrate WF2. As the planarization layer 910 is disposed, subsequent processes may be smoothly performed on the top surface of the second wafer substrate WF2. When the second wafer substrate WF2 is divided, the planarization layer 910 may be divided together to form the passivation layer 900 of the display device 10.

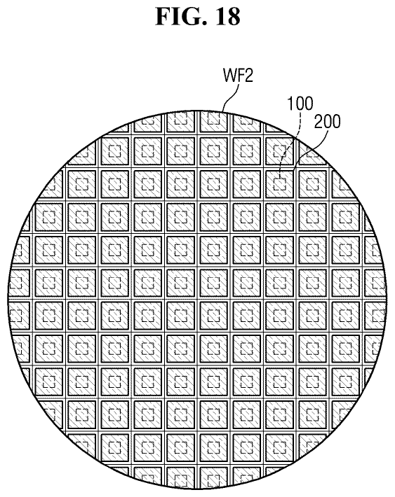

Next, referring to FIG. 18, the display element layer EML is formed on the top surface of the second wafer substrate WF2, which is opposite to the bottom surface where the driving unit 100 is attached, to form the display part 200. The process of forming the display element layer EML may be performed by a process different from the semiconductor process of forming the driving circuit layer 120 on the first wafer substrate WF1. For example, the process of forming the display element layer EML may be performed by a semiconductor process having a relatively large line width, and may be a process requiring relatively low cost compared to the process of forming the driving circuit layer 120.

In the process of forming the display element layer EML, the plurality of light emitting elements of the display element layer EML may be electrically connected to the conductive vias formed in the through holes TSV of the second single crystal semiconductor substrate 210 and the connection lines of the connection wiring layer 500, and may be electrically connected to the driving circuit layer 120 of the driving unit 100 or the pixel circuit portion 800 through the conductive vias and the connection lines. Further, in this process, the display element layer 230 including the display element layer EML, the encapsulation layer TFE, the optical layer OPL, and/or the like may be formed. As the display element layer 230 is formed on the second wafer substrate WF2, the display part 200 including the display element layer 230 may be formed.

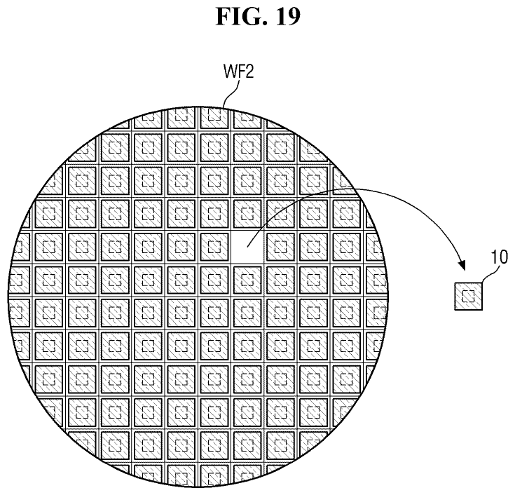

Next, referring to FIG. 19, the second wafer substrate WF2 may be divided into the second single crystal semiconductor substrates 210 on which the display element layers EML are formed. The display element layer 230 including the display element layer EML may be formed on the top surface of the divided second single crystal semiconductor substrate 210, and the connection wiring layer 500, the first single crystal semiconductor substrate 110, and the passivation layer 900 may be attached to the bottom surface thereof. Next, in one or more embodiments, the display device 10 may be fabricated by attaching the circuit board 300 to one surface of the display part 200.

In the method for fabrication of the display device 10 according to one or more embodiments, a process of forming elements of a circuit unit and a process of forming the light emitting elements may be performed on different wafer substrates WF1 and WF2, respectively. In the display device 10, the elements of the circuit unit and the light emitting elements may have different optimized fabrication processes, and in consideration of this, they may be formed through separate processes that can increase fabrication yield on different wafer substrates. In particular, because the process of forming the driving circuit layer 120 included in the driving unit 100 of the display device 10 is performed as a micro semiconductor process, the yield per unit area of the first wafer substrate WF1 may be improved. In addition, the process of forming the display part 200 of the display device 10 may be suitable because the space occupied by unnecessary elements other than the light emitting element may be reduced or minimized and a display device with a high resolution per unit area may be implemented.

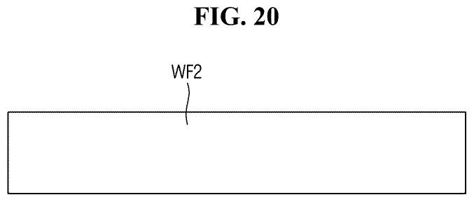

FIGS. 20-30 are cross-sectional views sequentially illustrating a fabrication process of a display device according to one or more embodiments. FIGS. 20-30 illustrate processes of forming the through holes TSV and the routing lines RM of the display part 200 and connecting them to the driving unit 100 in more detail. FIGS. 20-30 omits processes of forming the driving unit 100 on the first wafer substrate WF1 and dividing it.

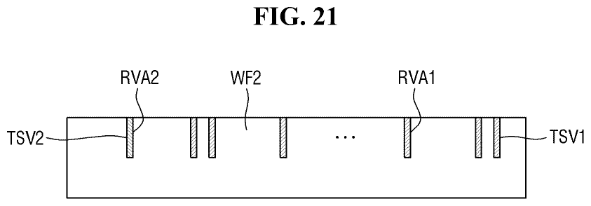

Referring to FIGS. 20 and 21, the second wafer substrate WF2 is prepared, and the plurality of through holes TSV1 and TSV2 partially penetrating the second wafer substrate WF2 and the conductive vias RVA1 and RVA2 disposed in the through holes TSV1 and TSV2 are formed. The plurality of through holes TSV1 and TSV2 may be disposed to be spaced (e.g., spaced apart) from each other. The first through holes TSV1 may be formed in an area of the second wafer substrate WF2, which corresponds to the display area DAA of the display part 200. The second through holes TSV2 may be formed in an area of the second wafer substrate WF2, which corresponds to the non-display area NA of the display part 200. The plurality of first conductive vias RVA1 may be formed to respectively fill the first through holes TSV1, and the plurality of second conductive vias RVA2 may be formed to respectively fill the second through holes TSV2.

The depths of the through holes TSV1 and TSV2 may be smaller than the thickness of the second wafer substrate WF2. As will be described later, a process of reducing the thickness of the second wafer substrate WF2 may be performed. In the process, the through holes TSV1 and TSV2 may penetrate the second wafer substrate WF2 whose thickness has been reduced.

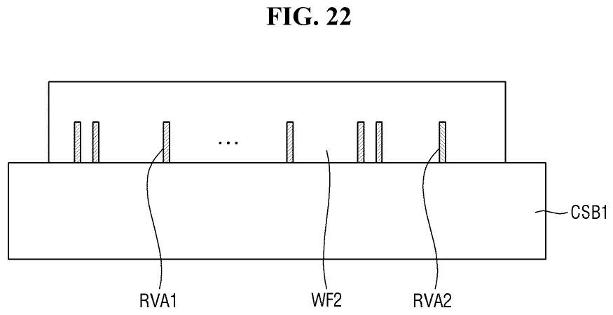

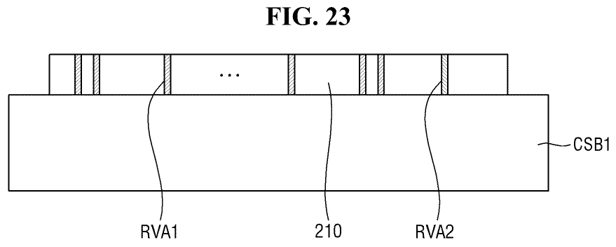

Referring to FIGS. 22 and 23, the second wafer substrate WF2 is moved onto a first carrier substrate CSB1, and then the thickness of the second wafer substrate WF2 is reduced, thereby forming the second single crystal semiconductor substrate 210. The first carrier substrate CSB1 may be attached to one surface of the second wafer substrate WF2 on which the through holes TSV1 and TSV2 are formed, for example, the top surface of the second wafer substrate WF2. The second wafer substrate WF2 may be turned over so that the other surface or bottom surface on which the through holes TSV1 and TSV2 are not formed faces upward, and the process of reducing the thickness of the second wafer substrate WF2 may be performed. In one or more embodiments, the thickness of the second wafer substrate WF2 may be reduced to be 100 μm or less, for example, in a range of 80 μm to 100 μm. After this process is performed, the plurality of through holes TSV1 and TSV2 may completely penetrate the second single crystal semiconductor substrate 210, and the plurality of conductive vias RVA1 and RVA2 may be exposed from the top and bottom surfaces of the second single crystal semiconductor substrate 210.

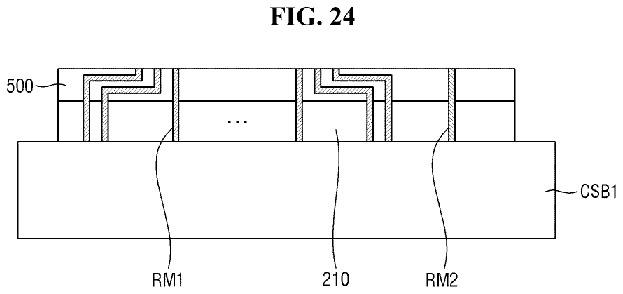

Referring to FIG. 24, the connection wiring layer 500 including connection lines is formed on one surface of the second single crystal semiconductor substrate 210, which is not in contact with the first carrier substrate CSB1, for example, the bottom surface thereof. The connection wiring layer 500 may include an interlayer insulating layer and a plurality of connection lines, and each of the connection lines may correspond to the first conductive via RVA1 or the second conductive via RVA2. The connection line connected to the first conductive via RVA1 may constitute the first routing line RM1 together with the first conductive via RVA1, and the connection line connected to the second conductive via RVA2 may constitute the second routing line RM2 together with the second conductive via RVA2.

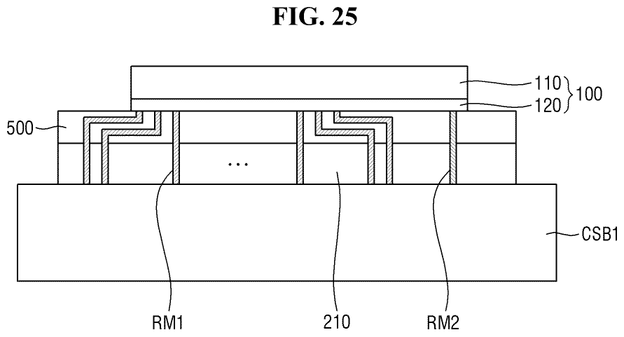

Referring to FIG. 25, the driving unit 100 including the first single crystal semiconductor substrate 110 and the driving circuit layer 120 is attached onto the connection wiring layer 500. The driving unit 100 may be formed on the first wafer substrate WF1 and divided therefrom, and may have a smaller area than that of the second single crystal semiconductor substrate 210. The plurality of routing lines RM1 and RM2 may be respectively connected to the pixel circuit portion 800 and the signal terminal STD of the driving unit 100.

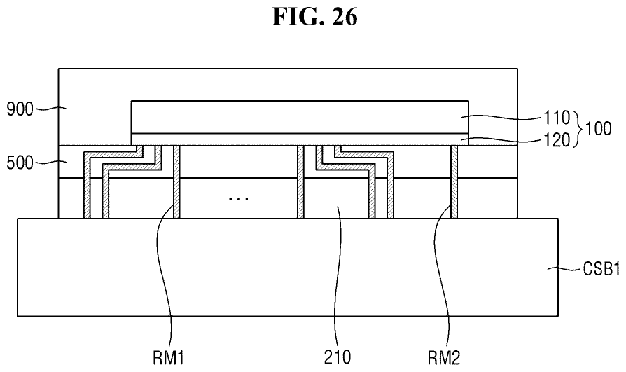

Referring to FIG. 26, the passivation layer 900 or a planarization layer is formed to cover the driving unit 100. The passivation layer 900 may compensate for a step caused by the driving unit 100 and protect the driving unit 100.

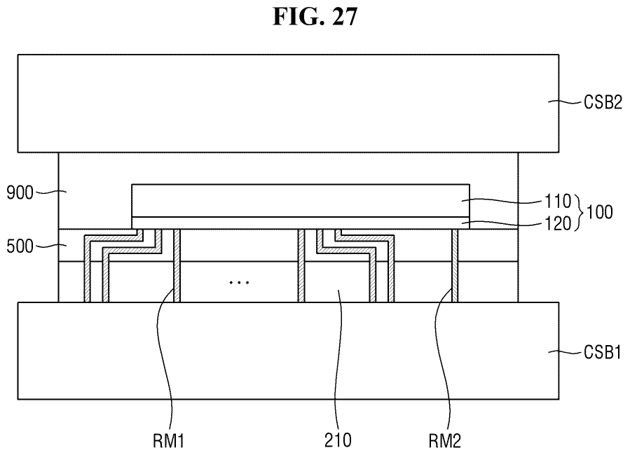

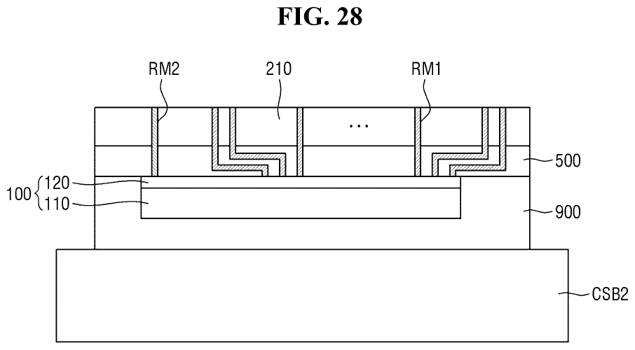

Referring to FIGS. 27 and 28, a second carrier substrate CSB2 is attached onto one surface of the passivation layer 900, it is turned over, and then the first carrier substrate CSB1 is removed. If the first carrier substrate CSB1 is removed, the top surface of the second single crystal semiconductor substrate 210 may be exposed.

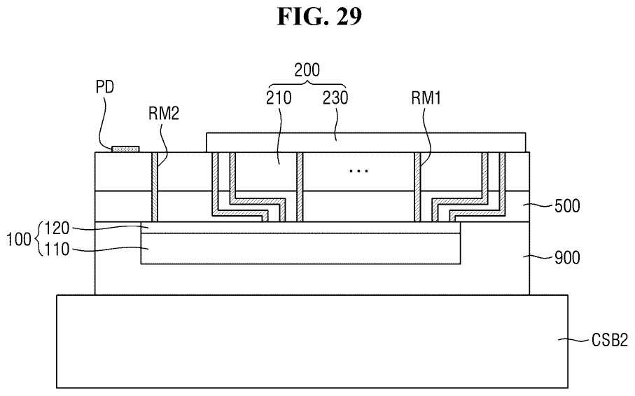

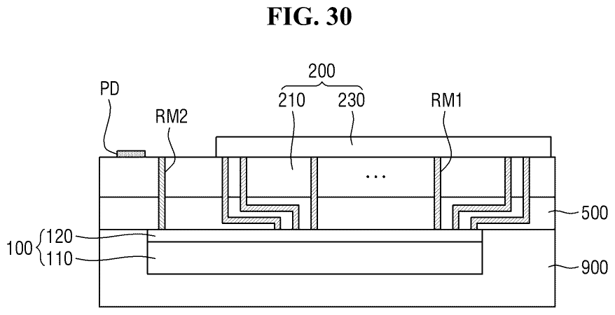

Referring to FIGS. 29 and 30, the display element layer 230 and the pad PD are formed on the second single crystal semiconductor substrate 210 to form the display part 200, and the second carrier substrate CSB2 is removed. In the process of forming the display element layer 230, the plurality of light emitting elements of the display element layer EML may be electrically connected to the first routing lines RM1, respectively. The light emitting elements may be electrically connected to the pixel circuit portion 800 of the driving unit 100 via the first routing lines RM1. The pads PD may be electrically connected to the signal terminal STD of the driving unit 100 via the second routing line RM2.

Next, in one or more embodiments, the circuit board 300 may be attached onto the pad PD of the display part 200, thereby fabricating the display device 10.

Hereinafter, various embodiments of the display device 10 will be described with reference to other drawings.

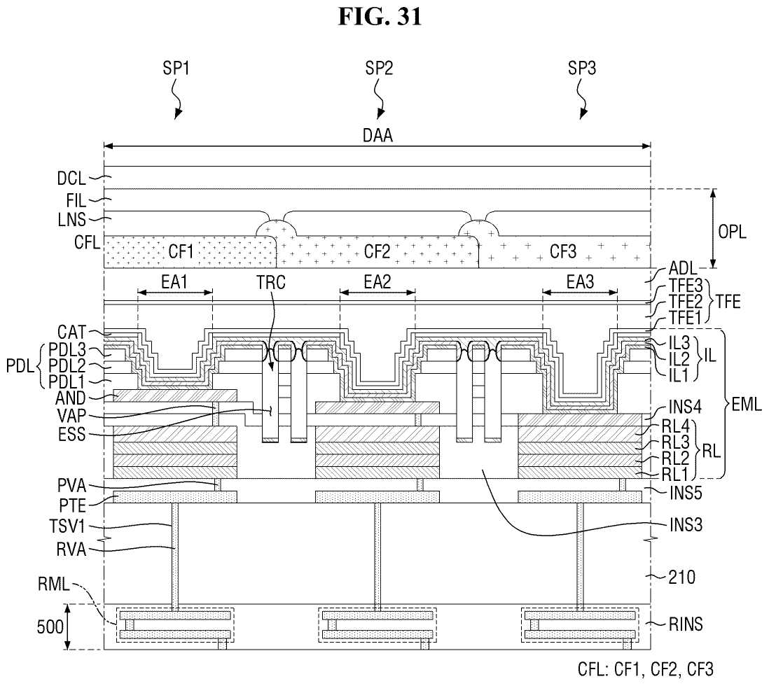

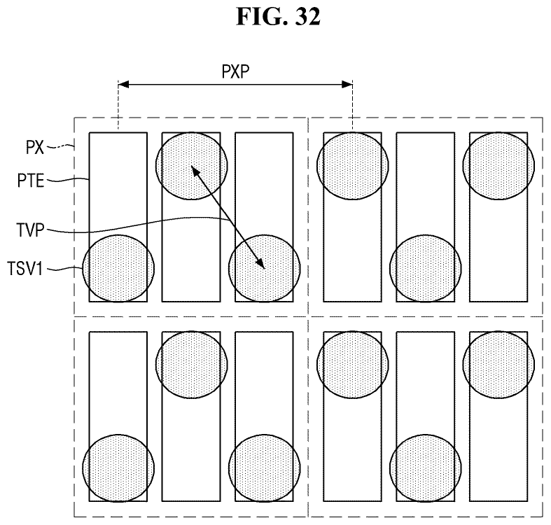

FIG. 31 is a cross-sectional view illustrating a part of a display part according to one or more embodiments. FIG. 32 is a plan view showing a schematic disposition of pixel areas and through holes disposed in a display area of the display part of the display device in FIG. 31.

Referring to FIGS. 31 and 32, the display part 200 of the display device 10 may include a plurality of conductive patterns PTE respectively corresponding to the sub-pixel portions PXS or the sub-pixels SP1, SP2, and SP3 of each pixel PX. The display part 200 may include the conductive patterns PTE and a fifth interlayer insulating layer INS5 disposed between the second single crystal semiconductor substrate 210 and the display element layer EML. The conductive pattern PTE may be in contact with the conductive via RVA disposed in the first through hole TSV1 penetrating the second single crystal semiconductor substrate 210, and may be connected to the first reflective electrode RL1 of the reflective electrode layer RL via a connection via PVA penetrating the fifth interlayer insulating layer INS5. The light emitting elements of the sub-pixel SP1, SP2, and SP3 may be electrically connected to the first routing lines RM1 via the reflective electrode layer RL and the conductive patterns PTE.

The conductive patterns PTE may have a shape extending in one direction in each pixel PX and may be disposed to be spaced (e.g., spaced apart) from each other. In one pixel PX, three conductive patterns PTE may be disposed with equal areas. Similar to the sub-pixel portions PXS, the conductive patterns PTE may respectively correspond to the sub-pixels SP1, SP2, and SP3. The first through holes TSV1 and the conductive vias RVA may be formed based on the disposition of the conductive patterns PTE. Further, the first electrodes AND of the light emitting elements included in the plurality of sub-pixels SP1, SP2, and SP3 may also be formed based on the disposition of the conductive patterns PTE. For example, the plurality of first through holes TSV1 may be formed to respectively overlap the conductive patterns PTE, and the conductive vias RVA may be respectively connected to the conductive patterns PTE. At least a portion of the first electrode AND of the light emitting element may overlap the conductive pattern PTE. Accordingly, the shape and disposition of the first electrode AND may be modified in various ways as long as the first electrode AND can be electrically connected to the conductive pattern PTE through the connection via PVA. The display device 10 according to one or more embodiments includes the conductive patterns PTE disposed in the display part 200, and thus it has freedom in layout design considered for the connection of the pixel circuit portion 800 and the light emitting elements, which are disposed on the two different substrates.

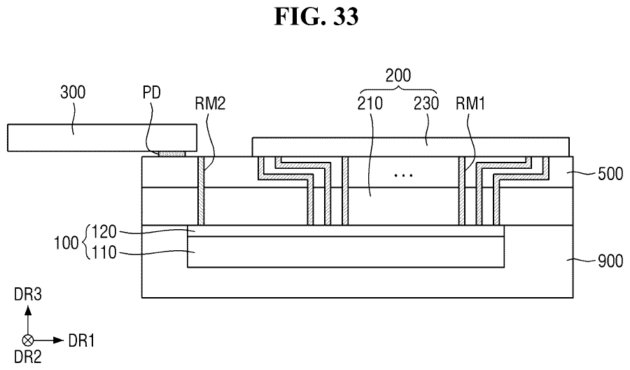

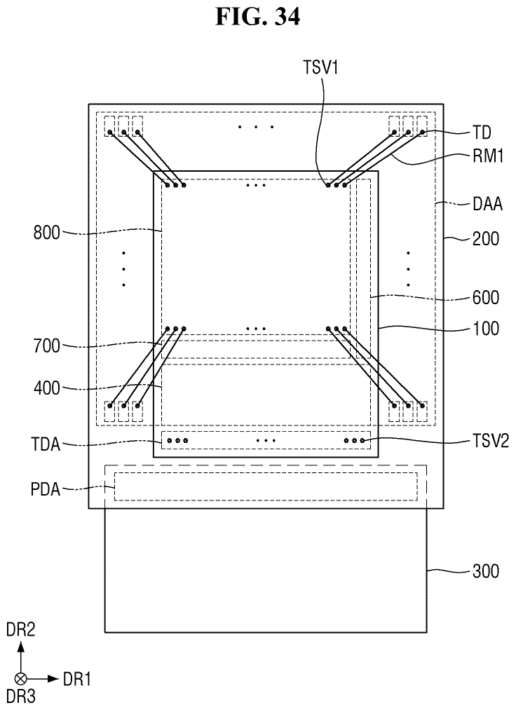

FIG. 33 is a schematic cross-sectional view of a display device according to one or more embodiments. FIG. 34 is a schematic diagram showing the rear surface of the display device of FIG. 33.

Referring to FIGS. 33 and 34, in the display device 10 according to one or more embodiments, the connection wiring layer 500 may be disposed between the display element layer 230 and the second single crystal semiconductor substrate 210. As the connection wiring layer 500 is disposed on the top surface rather than the bottom surface of the second single crystal semiconductor substrate 210, the locations of the connection lines RML, the conductive vias RVA, and the first through holes TSV1 are different from those of the embodiment of FIGS. 6 and 7.

The connection wiring layer 500 may be disposed on the top surface of the second single crystal semiconductor substrate 210. The interlayer insulating layer RINS of the connection wiring layer 500 may be disposed on the top surface of the second single crystal semiconductor substrate 210.

According to one or more embodiments, the plurality of first through holes TSV1 may overlap the driving unit 100 in the thickness direction (e.g., the third direction DR3). The first routing lines RM1 may be electrically connected to the sub-pixels SP1, SP2 and SP3 that are disposed throughout the display area DAA and may be connected between the first through holes TSV1 overlapping the driving unit 100 and the sub-pixels SP1, SP2, and SP3. For example, the connection lines RML of the first routing lines RM1 may be collected in the area where the first through holes TSV1 are disposed, and may be connected between a terminal TD connected to each of the sub-pixels SP1, SP2, and SP3 and the conductive via RVA disposed in the first through hole TSV1. In the display device 10, the plurality of first through holes TSV1 and the conductive vias RVA may each overlap the first single crystal semiconductor substrate 110 in the thickness direction. On the other hand, at least some of the connection lines RML may not overlap the first single crystal semiconductor substrate 110 in the thickness direction (e.g., the third direction DR3).

As described above, the area of the first single crystal semiconductor substrate 110 in a plan view may be smaller than the area of the second single crystal semiconductor substrate 210 in a plan view, and only some of the connection lines RML disposed over the entire surface of the second single crystal semiconductor substrate 210 may overlap the first single crystal semiconductor substrate 110 in the thickness direction (e.g., the third direction DR3). Accordingly, the connection lines RML may be disposed over the entire surface of the second single crystal semiconductor substrate 210, and the end of the connection line RML composed of several layers may overlap the first single crystal semiconductor substrate 110 in the thickness direction (e.g., the third direction DR3) and may be connected to the plurality of first through holes TSV1 and the conductive vias RVA. The connection lines RML may form a path electrically connecting the light emitting elements disposed in the entire display area DAA having a larger area to the pixel circuit portion 800 having a relatively smaller area.

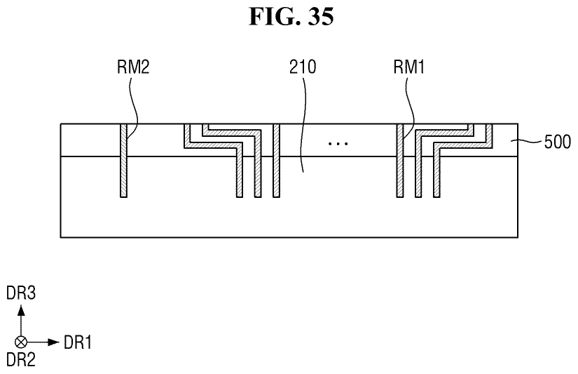

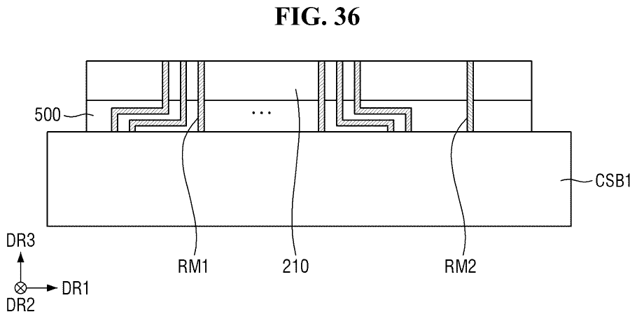

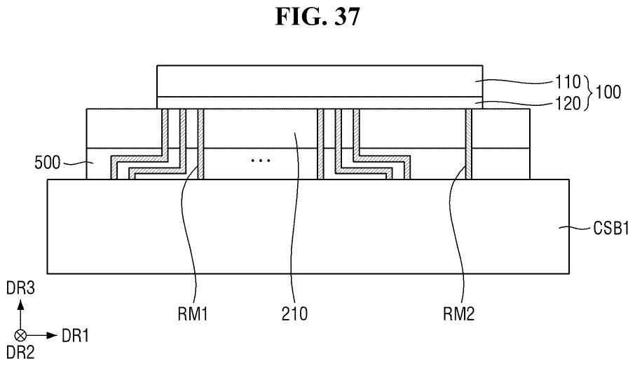

FIGS. 35-37 are cross-sectional views showing a part of the fabrication process of the display device of FIG. 33.

Referring to FIGS. 35-37, in the fabrication process of the display device 10, the second single crystal semiconductor substrate 210 may be formed through a process of reducing the thickness of the second wafer substrate WF2 after forming the plurality of through holes TSV1 and TSV2 and the conductive via RVA. In the display device 10 of FIG. 35, before performing the process of reducing the thickness of the second wafer substrate WF2, the plurality of routing lines RM1 and RM2 may be formed first by forming the connection wiring layer 500 on the top surface of the second wafer substrate WF2. Next, the process of reducing the thickness is performed on the rear surface of the second wafer substrate WF2 on which the connection wiring layer 500 is not disposed, thereby forming the second single crystal semiconductor substrate 210. Accordingly, the driving unit 100 may be attached onto the bottom surface of the second single crystal semiconductor substrate 210 on which the connection wiring layer 500 is not formed, and the display element layer 230 may be formed on the connection wiring layer 500. According to the manner of forming the connection wiring layer 500 and attaching the first single crystal semiconductor substrate 110, the relative disposition of the connection wiring layer 500, the second single crystal semiconductor substrate 210, and the first single crystal semiconductor substrate 110 disposed in the display device 10 may vary.

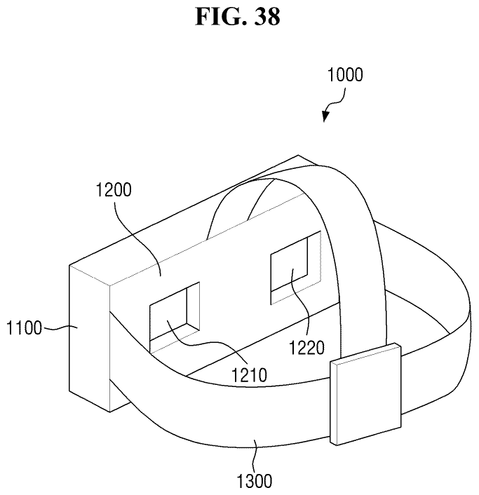

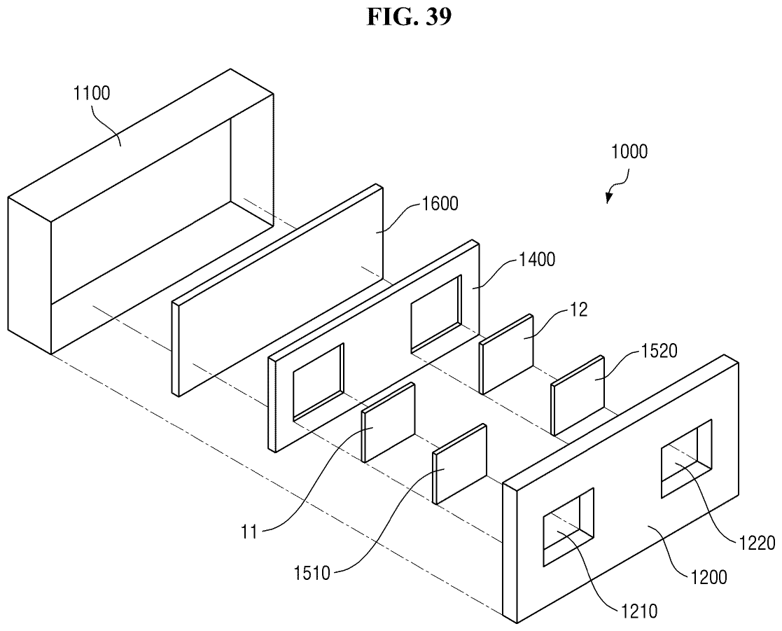

FIG. 38 is a perspective view illustrating a head mounted display device according to one or more embodiments. FIG. 39 is an exploded perspective view showing an example of the head mounted display device of FIG. 38.

Referring to FIGS. 38 and 39, a head mounted display device 1000 according to one or more embodiments includes a first display device 11, a second display device 12, a display device housing 1100, a housing cover 1200, a first eyepiece 1210, a second eyepiece 1220, a head mounted band 1300, a middle frame 1400, a first optical member 1510, a second optical member 1520, a control circuit board 1600, and a connector.

The first display device 11 provides an image to a user's left eye, and the second display device 12 provides an image to a user's right eye. Because each of the first display device 11 and the second display device 12 is substantially the same as the display device 10 described in conjunction with FIG. 1, the description of the first display device 11 and the second display device 12 will be omitted.

The first optical member 1510 may be disposed between the first display device 11 and the first eyepiece 1210. The second optical member 1520 may be disposed between the second display device 12 and the second eyepiece 1220. Each of the first optical member 1510 and the second optical member 1520 may include at least one convex lens.

The middle frame 1400 may be disposed between the first display device 11 and the control circuit board 1600 and between the second display device 12 and the control circuit board 1600. The middle frame 1400 serves to support and fix the first display device 11, the second display device 12, and the control circuit board 1600.

The control circuit board 1600 may be disposed between the middle frame 1400 and the display device housing 1100. The control circuit board 1600 may be connected to the first display device 11 and the second display device 12 through the connector. The control circuit board 1600 may convert an image source inputted from the outside into the digital video data DATA, and may transmit the digital video data DATA to the first display device 11 and the second display device 12 through the connector.

The control circuit board 1600 may transmit the digital video data DATA corresponding to a left-eye image optimized for the user's left eye to the first display device 11, and may transmit the digital video data DATA corresponding to a right-eye image optimized for the user's right eye to the second display device 12. Alternatively, the control circuit board 1600 may transmit the same digital video data DATA to the first display device 11 and the second display device 12.

The display device housing 1100 serves to accommodate the first display device 11, the second display device 12, the middle frame 1400, the first optical member 1510, the second optical member 1520, the control circuit board 1600, and the connector. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. It is illustrated in the drawing that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 11 and the first optical member 1510, and the second eyepiece 1220 may be aligned with the second display device 12 and the second optical member 1520. Accordingly, the user may view the image of the first display device 11 magnified as a virtual image by the first optical member 1510 through the first eyepiece 1210, and may view the image of the second display device 12 magnified as a virtual image by the second optical member 1520 through the second eyepiece 1220.

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1100 is implemented to be lightweight and compact, the head mounted display device 1000 may be provided with an eyeglass frame instead of the head mounted band 1300.

In addition, the head mounted display device 1000 may further include a battery for supplying power, an external memory slot for accommodating an external memory, and an external connection port and wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

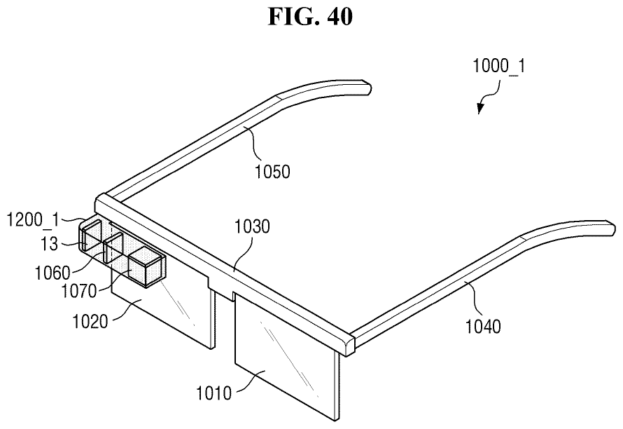

FIG. 40 is a perspective view illustrating a head mounted display device according to one or more embodiments.

Referring to FIG. 40, a head mounted display device 1000_1 according to one or more embodiments may be an eyeglasses-type display device in which a display device housing 1200_1 is implemented in a lightweight and compact manner. The head mounted display device 1000_1 according to one or more embodiments may include a display device 13, a left eye lens 1010, a right eye lens 1020, a support frame 1030, temples 1040 and 1050, an optical member 1060, an optical path changing member 1070, and the display device housing 1200_1.

The display device housing 1200_1 may include the display device 13, the optical member 1060, and the optical path changing member 1070. An image displayed on the display device 13 may be magnified by the optical member 1060, and the optical path may be changed by the optical path changing member 1070 to provide the image to the user's right eye through the right eye lens 1020. As a result, the user may view an augmented reality image, through the right eye, in which a virtual image displayed on the display device 13 and a real image seen through the right eye lens 1020 are combined.

It is illustrated in the drawing that the display device housing 1200_1 is disposed at the right end of the support frame 1030, but the present disclosure is not limited thereto. For example, the display device housing 1200_1 may be disposed on the left end of the support frame 1030, and in this case, the image of the display device 13 may be provided to the user's left eye. Alternatively, the display device housing 1200_1 may be disposed on both the left and right ends of the support frame 1030, and in this case, the user may view the image displayed on the display device 13 through both the left and right eyes.

In concluding the detailed description, those skilled in the art will appreciate that many variations and modifications can be made to the embodiments without substantially departing from the aspects of the present disclosure. Therefore, the embodiments of the present disclosure are used in a generic and descriptive sense only and not for purposes of limitation.

What is claimed is:

1. A display device comprising:
a first single crystal semiconductor substrate on which a plurality of first transistors is formed, a driving circuit layer being on the first single crystal semiconductor substrate;
a second single crystal semiconductor substrate on the first single crystal semiconductor substrate, the second single crystal semiconductor substrate having thereon a display element layer including a plurality of sub-pixels comprising a plurality of light emitting elements; and
a connection wiring layer between the display element layer and the first single crystal semiconductor substrate,
wherein the second single crystal semiconductor substrate includes a plurality of first through holes, and a conductive via in each of the plurality of first through holes, the conductive via being electrically connected to the light emitting element of each of the plurality of sub-pixels, and
wherein the connection wiring layer comprises a connection line electrically connected to the conductive via and the driving circuit layer.

2. The display device of claim 1, wherein the plurality of first through holes respectively corresponds to the plurality of sub-pixels, and
wherein the first through holes that respectively correspond to neighboring sub-pixels from among the plurality of sub-pixels are spaced in a diagonal direction.

3. The display device of claim 2, further comprising a plurality of pixels, each of the plurality of pixels having three sub-pixel portions respectively corresponding to the plurality of sub-pixels,
wherein a distance between centers of adjacent ones of the first through holes in the pixel is 61.0328% or less of a distance between same sub-pixel portions in neighboring pixels.

4. The display device of claim 1, further comprising a plurality of conductive patterns on the second single crystal semiconductor substrate and respectively correspond to the plurality of sub-pixels.

5. The display device of claim 4, wherein the plurality of first through holes respectively overlaps the conductive patterns, and
wherein the conductive via is connected to the conductive pattern.

6. The display device of claim 4, wherein a first electrode of each of the plurality of light emitting elements at least partially overlaps the conductive pattern.

7. The display device of claim 1, wherein the connection wiring layer is located between the second single crystal semiconductor substrate and the first single crystal semiconductor substrate.

8. The display device of claim 7, wherein some of the plurality of first through holes overlap the first single crystal semiconductor substrate, and other ones of the plurality of first through holes do not overlap the first single crystal semiconductor substrate.

9. The display device of claim 1, wherein the connection wiring layer is located between the second single crystal semiconductor substrate and the display element layer.

10. The display device of claim 9, wherein the plurality of first through holes overlaps the first single crystal semiconductor substrate.

11. The display device of claim 1, further comprising a plurality of signal terminals on the first single crystal semiconductor substrate,
wherein the second single crystal semiconductor substrate includes a plurality of second through holes overlapping the plurality of signal terminals.

12. The display device of claim 1, wherein an area of the first single crystal semiconductor substrate in a plan view is smaller than an area of the second single crystal semiconductor substrate in the plan view.

13. The display device of claim 1, further comprising a passivation layer around the first single crystal semiconductor substrate and overlapping the second single crystal semiconductor substrate.

14. A method for fabrication of a display device, the method comprising:
preparing a first wafer substrate and a second wafer substrate different from each other;
forming a plurality of first transistors on the first wafer substrate, and forming a plurality of through holes at least partially penetrating the second wafer substrate and a plurality of conductive vias respectively located in the plurality of through holes in the second wafer substrate;
dividing the first wafer substrate into a plurality of first single crystal semiconductor substrates, and disposing the first single crystal semiconductor substrate on one surface of the second wafer substrate;
forming a planarization layer covering the one surface of the second wafer substrate and the first single crystal semiconductor substrates attached to the one surface;
forming a display element layer comprising a plurality of light emitting elements on an other surface of the second wafer substrate opposite to the one surface; and
dividing the second wafer substrate into a plurality of second single crystal semiconductor substrates in which the display element layer is formed on an other surface and the first single crystal semiconductor substrate is located on the one surface,
wherein the plurality of conductive vias are respectively connected to the plurality of light emitting elements, and at least some of the plurality of through holes overlap the first single crystal semiconductor substrate.

15. The method of claim 14, wherein the plurality of through holes are spaced from other neighboring through holes in a diagonal direction.

16. The method of claim 14, further comprising, after forming the plurality of through holes and the plurality of conductive vias,
etching the second wafer substrate to reduce its thickness; and
forming a connection wiring layer comprising a plurality of connection lines connected to the conductive via on the one surface of the second wafer substrate where the through holes are not formed,
wherein the first single crystal semiconductor substrate is attached onto the connection wiring layer.

17. The method of claim 16, wherein some of the plurality of through holes overlap the first single crystal semiconductor substrate, and others do not overlap the first single crystal semiconductor substrate.

18. The method of claim 14, further comprising, after forming the plurality of through holes and the plurality of conductive vias,
forming a connection wiring layer comprising a plurality of connection lines connected to the conductive via on the other surface of the second wafer substrate opposite the one surface; and
etching the second wafer substrate to reduce its thickness,
wherein the first single crystal semiconductor substrate is attached onto the one surface of the second wafer substrate.

19. The method of claim 18, wherein the plurality of through holes overlaps the first single crystal semiconductor substrate.

20. A head mounted display device comprising:
a frame mounted on a user's body and corresponding to left and right eyes;
a plurality of display devices located in the frame; and
a lens on each of the plurality of display devices,
wherein the display device comprises:
a first single crystal semiconductor substrate on which a plurality of first transistors is formed, a driving circuit layer being on the first single crystal semiconductor substrate;
a second single crystal semiconductor substrate on the first single crystal semiconductor substrate, the second single crystal semiconductor substrate having thereon a display element layer having a plurality of sub-pixels comprising a plurality of light emitting elements; and
a connection wiring layer between the display element layer and the first single crystal semiconductor substrate,
wherein the second single crystal semiconductor substrate includes a plurality of first through holes, and a conductive via in each of the plurality of first through holes, the conductive via being electrically connected to the light emitting element of each of the plurality of sub-pixels, and
wherein the connection wiring layer comprises a connection line electrically connected to the conductive via and the driving circuit layer.
